(19) United States
(12) Patent Application Publication
(10) Pub. No.: US 2015/0132872 A1
(43) Pub. Date: May 14, 2015

(54) DEVICE AND METHOD FOR THE SURFACE TREATMENT OF A SUBSTRATE AND METHOD FOR PRODUCING AN OPTOELECTRONIC COMPONENT

(71) Applicant: OSRAM GmbH, Muenchen (DE)

(72) Inventors: Juergen Bauer, Wielenbach (DE); Gerhard Doell, Augsburg (DE); Klaus-Dieter Bauer, Landau (DE); Philipp Erhard, Mering (DE); Frank Vollkommer, Gauting (DE)

(21) Appl. No.: 14/397,207

(22) PCT Filed: Apr. 26, 2013
(86) PCT No.: PCT/EP2013/058741

§ 371 Date: Oct. 27, 2014

(30) Foreign Application Priority Data
Apr. 30, 2012 (DE) 10 2012 207 172.5

(51) Int. Cl. C23C 16/455; H01L 51/00; H01L 51/44; H01L 51/52; H01L 51/56

(52) U.S. Cl. CPC C23C 16/45525; C23C 16/455; H01L 51/5237; H01L 51/5206; H01L 51/5221; H01L 51/5262; H01L 51/56; H01L 51/441; H01L 51/448; H01L 51/44; H01L 51/0002; H01L 51/0021
USPC 438/26; 118/715; 427/255.28; 438/22; 438/29; 438/46; 438/98; 438/82; 438/69; 438/57; 438/64

(57) ABSTRACT

Various embodiments may relate to a device for the surface treatment of a substrate, including a processing head, which is mounted rotatably about an axis of rotation, and which comprises multiple gas outlets, which are at least partially implemented on a radial outer edge of the processing head.

### RELATED APPLICATIONS

The present application is a national stage entry according to 35 U.S.C. §371 of PCT application No. PCT/EP2013/058741 filed on Apr. 26, 2013, which claims priority from German application No.: 10 2012 207 172.5 filed on Apr. 30, 2012, and is incorporated herein by reference in its entirety.

### TECHNICAL FIELD

Various embodiments generally relate to a device and a method for the surface treatment of a substrate and a method for producing an optoelectronic component.

### BACKGROUND

Electronic components on substrates, for example, on flexible substrates, the functional layers of which are built up from organic and/or organometallic materials, are frequently protected from oxygen and water. For example, optoelectronic components having organic functional layers frequently have encapsulation layers under and/or above the organic functional layers, which protect the organic functional layers, for example, from moisture. The encapsulation layers are applied by means of deposition methods, for example, by means of atomic layer deposition or chemical gas phase deposition, for example. Examples of such systems are optoelectronic components, for example, light-absorbing or light-emitting cells, e.g., electrochemical cells and OLEDs, but also organic solar cells. In all of these systems, the service life and performance is very substantially dependent on the quality of the encapsulation.

In a conventional device for the surface treatment of a substrate or a corresponding method, in particular in a coating method for producing an optoelectronic component, which has the substrate, the substrate can be coated using different layers, for example, the organic functional layers and/or the encapsulation layers. These layers can only have a few atomic layers or can be up to several hundred nanometers thick. The layers can be applied, for example, using CVD (chemical vapor deposition) methods or ALD (atomic layer deposition) methods. The disadvantage of these methods, for example, the ALD method, however, is the quite time-consuming processing, which has layer growth rates of approximately 1 Å per coating process. For this reason, coatings of substrate formations (batches) are most frequently performed in larger ALD reactors having corresponding processing chambers for accommodating the substrate formations, in which multiple components are coated simultaneously for several hours. In this case, the substrates are coated in a large substrate formation, for example, from which the individual substrates are separated in a following process, for example, the substrate formation is a wafer or a substrate plate. In addition, encapsulation can be performed by means of glass plates.

The substrate to be coated, for example, in the substrate formation, can be introduced into the processing chamber, to which one, two, or multiple process gases are supplied successively. The process gases include reaction gases, for example, and are used for the purpose of depositing atoms and/or molecules on the substrate and forming the layers by reaction, and/or the process gases have a flushing gas, which is used to flush the processing chamber, to subsequently be able to introduce a reaction gas, which is not permitted to mix with a previously introduced reaction gas or which at least can only form a compound with atoms or molecules of the previously introduced reaction gas on the surface of the substrate, for example, in the ALD process. Furthermore, the reaction gases can be mixed gases, which include a reactive gas and a carrier gas. Between the individual process steps, during which process gases are supplied to the processing chamber, one, two, or more process steps can be carried out, during which the supplied process gases are suctioned out again and/or a partial vacuum is generated in the processing chamber. For example, this can always be performed before and after the supply of the flushing gas.

In the case of coating of a large quantity of substrates, several problems arise. For example, only a limited quantity of substrates can be introduced into the processing chamber. In addition, it can be necessary depending on the coating process to supply the same and/or different process gases to the processing chamber multiple times for coating the quantity of substrates and to suction them out again and again in the meantime, wherein a loss of process gas results. In addition, in regions (dead spaces) which lie outside the predominant gas flow, long processing times and/or quality problems due to contaminants can arise by way of the more difficult gas exchange therein. Furthermore, severe damage results if a processing step is faulty, since the entire quantity of substrates or the entire substrate formation can be affected and can no longer be used thereafter. Furthermore, the continuous introduction and removal of the substrates into or from the processing chamber and the possibly frequent filling and suctioning out of the processing chamber results in a long processing duration during the coating of the substrates.

Using movable processing heads to avoid the mentioned disadvantages is known as an alternative to the stationary processing chamber. In particular in the case of the production of flexible solar cells and flexible light-emitting systems, for example, the attempt has been made to use roll-to-roll (R2R) methods, in which a substrate or substrate formation is unrolled from a roll, treated on the piece, and rolled back onto a roll after the treatment or separated, to be able to produce more efficiently and cost-effectively. Of course, for example, the encapsulation steps should also be carried out as compatibly as possible with these processes.

In the case of flexible systems, it is often desirable that the flexibility is not lost due to a glass encapsulation. Therefore, thin closed layers are frequently used for the encapsulation. To produce these layers, the ALD method is frequently mentioned in the literature, since in this way dense and conformal layers, i.e., layers which also enclose three-dimensional structures, can be produced. The ALD method is a method in which one atomic layer of a layer, for example, of a metal oxide layer, is applied in each case. This is performed by covering the surface of the substrate to be coated using a first reaction gas (for example, water vapor), which is also called precursor 1 or first educt. After the first educt is pumped out, a monolayer of the adsorbed first educt remains on the surface. Subsequently, a second reaction gas (for example, TMA, trimethyl aluminum) is supplied, which is also called precursor 2 or second educt. This now reacts with the first educt remaining on the surface and forms a mono-atomic layer of the corresponding solid reaction product on the surface, for example, a metal oxide (Al2O3). Between the supply of the different reaction gases, the processing chamber must be pumped out and/or flushed using an inert gas, to remove gaseous reaction products and unreacted residues of the respective precursor. Mixing of precursor 1 and precursor 2 and an undesired reaction of the two substances in the gas phase is thus also avoided.

Various approaches are known for the rapid ALD coating of flexible substrates:

For example, an ALD coating processing head can have slotted gas outlets, which are used to cause the precursors to flow over the substrate (see “Towards a Roll-to-Roll ALD process”, D. Cameron et al., ASTRal, MIICS 2010, page 15). In addition to the gas outlets for the precursors, the head also carries gas outlets for a flushing gas, and also gas inlets for suctioning out the different gases. This coating head is now moved alternately laterally and forward/backward in relation to the substrate (movements transversely to the substrate are also conceivable, of course). One movement cycle corresponds to two layer growth cycles, since both precursors are applied with each movement, which together form a layer. The necessity of the coating direction reversal is always linked to positive and negative accelerations. Therefore, acceptable coating velocities can only be achieved by long, large facilities. However, a large space demand automatically means particle freedom which is more difficult to monitor and, in the case of a stationary ALD coating processing head, long gas lines or a large outlay in the web guiding and web movement of the flexible substrate. Compact ALD coating units having high throughput therefore cannot be implemented using this method. In addition, acceleration sections, for example, at front and rear or lateral reversal points of the processing head, can possibly result in inhomogeneities in the layer quality.

As an alternative, an ALD processing unit is known from the above-mentioned publication, which displays a radially-symmetric coating processing head, the gas outlets of which point in the direction of the center. A substrate section, the length of which is somewhat shorter than an internal circumference of the coating head, is separated from a substrate formation, which includes an endless substrate, for example, which is wound onto a roll. The separated substrate section is stretched on a circular substrate holder, which is arranged within the processing head. The substrate holder with the substrate section is then rotated and coated at the same time with the aid of the processing head, wherein during one revolution, for example, one, two, or more identical or different layers can be applied to the substrate section. At a high rotational velocity, many layers can thus be applied rapidly to the substrate section. However, the arrangement shown has the disadvantage of the necessity of having to unroll the flexible substrates from the roll, separate them, and stretch them as already separated substrate sections successively on a roller-shaped substrate holder, which rotates coaxially within the processing head. The roll-to-roll process is therefore abandoned, however, with the advantage of being able to build up the layers substantially more rapidly. Specifically, the coating velocity is essentially predefined by the rotational velocity of the substrate holder. Furthermore, acceleration sections are dispensed with, for example, by omitting reversal points.

Further methods known from the mentioned publication operate using different gas zones. The disadvantage in this case is the reliable avoidance of gas inter-diffusion, and the necessity of having to redirect the substrates to be coated in the order of magnitude of one hundred times or more, without damaging or contaminating the layers.

### SUMMARY

In various embodiments, a device and a method for the surface treatment of a substrate are provided, in which a surface of the substrate can be treated simply and rapidly. Furthermore, in various embodiments, a method for producing an optoelectronic component is provided, in which a surface of the substrate of the optoelectronic component may be treated simply and rapidly. The surface treatment may include, for example, a coating of the substrate and/or the substrate may be a flexible substrate and/or the method may be part of a roll-to-roll method, for example, for coating multiple substrates, for example, flexible substrates, for example, without having to previously separate the flexible substrates (R2R, not batch operation).

In various embodiments, a device for the surface treatment of a substrate is provided. The device has a processing head, which is mounted rotatably about an axis of rotation. The processing head includes multiple gas outlets, which are at least partially implemented on a radial outer edge of the processing head.

The gas outlets on the radial outer edge enable the substrate to be arranged on the outer edge of the processing head and/or, in the case of a flexible substrate, the flexible substrate to be arranged guided at least partially around the radial outer edge of the processing head, and the side of the substrate facing toward the processing head to be treated. In conjunction with the rotatably mounted processing head, this enables an endless substrate, for example, an endless film, for example, directly following the film production process, to be gradually guided past the outer edge of the processing head, and the endless substrate to be treated. This enables the surface treatment to be carried out rapidly, simply, and/or in a roll-to-roll method, for example. For example, during the surface treatment, the flexible substrate may be coated, for example, in a CVD process and/or, for example, in an ALD process. The process gases required for this purpose may be supplied via the gas outlets on the radial outer edge. The fact that the substrate is flexible means, for example, that the substrate may be guided at least partially around the processing head, without being damaged in this case. This may also be dependent on the radius of the processing head and the curvature of the substrate thus predefined, for example.

The rotatable processing head having the gas outlets on the radial outer edge enables a surface treatment of the substrate, for example, the flexible substrate, with low gas consumption and high processing velocity, in particular if multiple gases are required successively per layer and/or if multiple identical or different layers must be applied or removed one on top of another. Furthermore, the device may be implemented very compactly and may be incorporated simply into an existing production line. Furthermore, in the event of an incorrect treatment, only a small part of the flexible substrate, in particular the part applied to the processing head, is flawed and may be removed without great harm.

The flexible substrate may, for example, be unrolled from a roll, treated with the aid of the processing head, and rolled onto another roll again, for example, without a separation process. Alternatively thereto, the flexible substrate may be separated directly after the treatment. The flexible substrate includes, for example, a Kapton film, a metal film, or a PET film. The flexible substrate may already be coated, for example, using an organic functional layer structure for emitting or absorbing light, using one or more optical functional layers, such as scattering layers or refraction layers, and/or using one or more electrode layers. In other words, a stack of layers may already be implemented on the substrate, which is then coated with the aid of the rotatable processing head. Alternatively thereto, these layers may be applied to the substrate in the course of the surface treatment. In this context, during the surface treatment, for example, an encapsulation layer may be applied, for example, according to an ALD method. Alternatively thereto, one or more barrier layers, optical layers, and/or one or more thin-film transistors may also be applied.

According to various embodiments, the gas outlets are implemented and arranged so that in operation a process gas leaves at least one of the gas outlets, so that it flows away from the processing head at least partially in a direction having a radially oriented directional component. In other words, the process gas flows out of the gas outlet up to the flexible substrate, wherein the stream of the process gas may be oriented directly onto the substrate, and/or the process gas may be directed onto the processing head itself and then indirectly flow toward the substrate. This contributes to the flexible substrate arranged around the outer edge being uniformly coated. For example, the process gas may be blown in the radial direction, i.e., perpendicularly to the axis of rotation, out of the processing head; however, the process gas may also be blown out of the processing head only partially oriented in the radial direction, for example, in consideration of a flow optimization with rotating processing head. For example, the gas outlets may be implemented in a flow-optimized manner.

According to various embodiments, the processing head is implemented as cylindrical, for example, according to a right cylinder, and includes an axis and a jacket surface, wherein the axis is a straight line, for example, which extends through the center points of the base surface and cover surface of the cylinder. In other words, the processing head may be implemented as drum-shaped. The axis lies on the axis of rotation, for example, and the gas outlets arranged on the outer edge are implemented on the jacket surface. This enables the gas outlets to be positioned on the radial outer edge in a simple manner, the flexible substrate to be arranged around the radial outer edge or the jacket surface, and the surface to be coated of the flexible substrate to be coated uniformly. In the axial direction, the processing head, depending on the width of the substrate to be treated, for example, may be between 1 mm and 10 000 mm, for example, between 10 mm and 1000 mm, for example, between 100 mm and 500 mm wide. The radius of the processing head may be, for example, between 10 mm and 1000 mm, for example, between 100 mm and 600 mm.

According to various embodiments, at least one gas inlet is implemented on the radial outer edge of the processing head. This enables process gas which was introduced, for example, via the gas outlets between the flexible substrate and processing head to be removed again, for example, to be suctioned out. The gas inlet on the radial outer edge may be implemented according to one of the gas outlets or differently thereto, for example, on the jacket surface of the processing head.

According to various embodiments, at least one gas outlet and/or the at least one gas inlet, which is arranged on the radial outer edge, are implemented as slotted and/or circular. For example, the corresponding gas outlet or gas inlet may have one or more slotted or circular recess(es) in the radial outer edge, for example, the jacket. The slot may extend, for example, from one axial end of the processing head to the other axial end of the processing head, for example, parallel to the axis of rotation and/or tangentially on the jacket surface of the processing head. Alternatively or additionally, multiple circular recesses may be arranged along one or more straight lines from one axial end of the processing head to the other axial end of the processing head, for example. This contributes to the surface to be coated of the flexible substrate being uniformly coated. Alternatively thereto, one, two, or more slotted or circular outlets, for example, may jointly form one gas outlet. Furthermore, the recesses may be implemented as polygonal and/or in a flow-optimized manner.

According to various embodiments, the processing head has a first gas outlet for supplying a first reaction gas to a first processing chamber, a second gas outlet for supplying a second reaction gas to a second processing chamber, and a further gas outlet for supplying a flushing gas to a flushing region, which may also be referred to as a further processing chamber. The reaction gases and the flushing gas may also be referred to as process gases. In addition, the processing head may have one, two, or multiple gas inlets, via which the reaction gases and/or the flushing gas are suctioned out, distributed peripherally around the circumference between the gas outlets in each case. This enables, for example, three different process gases to be supplied, for example, in the course of an ALD method, as a first reaction gas, a first gaseous educt (starting material) and, as a second reaction gas, a second gaseous educt for producing a layer made of a first material or a first material combination, and the flushing gas. During the ALD process, the first and second gaseous educts are also referred to as the first and second precursors, respectively. In addition, still further gas outlets may be provided, for example, two further educts may be supplied, for example, for producing a layer made of a second material or a second material combination, or multiple gas outlets may also be provided for supplying the first and/or second educt. For example, one gas outlet for the flushing gas may always be provided between two gas outlets for the educts in each case. Furthermore, one gas inlet for suctioning out the educts may be provided in each case between the gas outlets of the educts. Thus, for example, along the circumference of the radial outer edge, one gas outlet for the first educt, one gas inlet for suctioning out the first educt, one gas outlet for the flushing gas, one gas inlet for suctioning out the flushing gas, one gas outlet for the second educt, one gas inlet for suctioning out the second educt, another gas outlet for the flushing gas, and one gas inlet for suctioning out the flushing gas may be provided successively. This sequence may be repeated multiple times and/or still further gas outlets for further educts and/or further gas inlets may be provided.

According to various embodiments, the device includes a housing, in which the processing head is rotatably mounted and which includes a supply opening for supplying the substrate, for example, the flexible substrate, and a discharge opening for discharging the substrate. The housing enables, for example, an environment of the device to be protected from the process gases, the processing region to be controlled in temperature, and/or the substrate to be protected. One element of a feed device may be implemented in each case in the region of the supply opening and/or in the region of the discharge opening. The feed device may optionally contribute to feeding the substrate into the housing and/or drawing it out of the housing. For example, the feed device may have one, two, or multiple rollers, which are actively or passively rotatable, for example. Furthermore, the feed device may be integrated into the housing so that it represents a part of the housing and/or the supply opening and/or the discharge opening. For example, the supply opening and/or the discharge opening may be formed by a slot between a roller of the feed device and the housing in each case.

According to various embodiments, the device has a heating device, which heats an interior of the housing. The heating device may contribute in a particularly simple manner to achieving a processing temperature for the surface treatment, if the corresponding process requires it. During the performance of the surface treatment, a temperature in the housing between 0° and 1000° C. may be produced, for example, between 10° and 500° C., for example, between 20° and 250° C., for example, approximately 200° C. Alternatively thereto, surface treatments may be performed at room temperature.

According to various embodiments, the device has a housing suction unit for suctioning gas out of the housing. The gas may have air or process gas, for example. This may contribute to preventing process gas from exiting into the environment of the device. The housing suction unit may have multiple suction units, for example, which allow a step-by-step and/or differential suctioning out of the gas, for example. By way of a sequential arrangement of suction units according to the principle of differential pumping, for example, ambient air may be prevented from entering the housing, for example, if the housing internal pressure is below the ambient pressure, or process gas may be prevented from exiting the housing, for example, if the housing internal pressure is above the ambient pressure. The housing suctioning out may be performed, for example, on the side of the substrate to be coated or on the side of the substrate not to be coated, for example, in the region of the feed device, between the supply openings or in the region of the processing head. Furthermore, a suction unit may be arranged in the housing so that it generates a partial vacuum on the side of the substrate not to be coated, so that the substrate is suctioned away from the processing head and thus has a predefined distance to the processing head.

According to various embodiments, the housing includes a housing flushing gas supply for supplying flushing gas into the housing. In this context, the housing may be heated with the aid of heated flushing gas, for example. The flushing gas may be supplied, for example, on the side of the substrate to be coated or on the side not to be coated, for example, in the region of the feed device, between the supply openings or in the region of the processing head. The housing flushing gas supply may cooperate with the suction unit, for example, to protect the environment of the device from process gases.

According to various embodiments, the device has the feed device for feeding the substrate, for example, the flexible substrate, toward the processing head and guiding the substrate further away from the processing head. This enables in a simple manner a roll-to-roll method to be performed. The feed device may have, for example, one, two, or multiple rotatable rolls or the above-mentioned rollers, the axes of rotation of which may be implemented in parallel to the axis of rotation of the processing head, for example.

According to various embodiments, the processing head has two or more spacers for applying the substrate to the processing head. The spacers may be implemented adjacent to the processing head or on the processing head itself. For example, the spacers may protrude from the jacket of the processing head in the radial direction and/or may be rotatably mounted in relation to the processing head. In operation, the flexible substrate is at least partially guided around the processing head so that it rests on the spacers. The surface to be coated and the processing head then delimit one or more processing chambers, to which the process gases are supplied. The spacers are implemented, for example, so that the substrate has, for example, a distance from the jacket surface of the processing head between 0.01 and 10 mm, for example, between 0.05 and 5 mm, for example, between 0.1 and 1 mm. The processing chamber or chambers then has/have, with applied flexible substrate, a height between 0.01 and 10 mm, or between 0.05 and 5 mm, or between 0.1 and 1 mm, respectively. Alternatively or additionally, the spacing between the processing head and the substrate may be set via an overpressure in the processing chamber or chambers or via a partial vacuum on the side of the substrate facing away from the processing chamber or chambers.

According to various embodiments, the spacers include at least two webs, which are arranged at the axial outer edges of the processing head. The webs are rotatably mounted in relation to the processing head, for example. The webs are fastened in the housing independently of the processing head or on the processing head, for example. In operation, the flexible substrate is guided at least partially over the webs and around the processing head so that the edge which is not to be coated of the surface to be coated of the substrate is applied to the webs. The surface to be coated, the processing head, and the webs then delimit one or more processing chambers, to which the process gases are supplied. The webs may have, for example, a width between 1 and 20 mm, for example, between 5 and 15 mm. Furthermore, one, two, or more further webs may be arranged between the webs at the axial ends of the processing head, to prevent the flexible substrate from sagging in the direction of the jacket surface. The number and the width of the webs may be selected, for example, in dependence on the axial length of the processing head and/or the width and/or the stability of the flexible substrate. Alternatively or additionally, the jacket surface may be implemented so that the substrate may sag between the outer webs, without the spacing to the jacket surface varying. For example, the jacket surface may be implemented as concave, i.e., curved inward. The radial jacket surfaces of the webs may represent continuous or spot-shaped support surfaces for the substrate, for example. The gas outlets are implemented between the webs, for example. For example, the gas outlets extend from one of the webs to another of the webs.

In addition to the webs, fixing elements may be provided, which are used for the purpose of fixing the substrate on the webs during its revolution around the processing head in the feed direction. For example, the webs may include pins and the substrate may include holes corresponding to the pins, so that the pins engage in the holes and the substrate is fixed in relation to the rotatably mounted webs. Alternatively thereto, the fixing elements may also include one or more clamping devices, with the aid of which the substrate may be clamped and/or stretched in the axial direction, for example, automatically.

According to various embodiments, the device includes multiple transverse walls on its radial outer edge, which protrude in the radial direction from the radial outer edge and which extend in one direction having at least one directional component in the axial direction. In other words, at least one directional component of the extension direction of the transverse walls is parallel to the axis of rotation of the processing head. In other words, the transverse walls form tangents on the jacket surface. The transverse walls divide the circumference of the processing head into multiple segments. The transverse walls may optionally be used, for example, as spacers, for predefining a spacing between the radial outer edge, for example, the jacket surface, of the processing head and the substrate. The transverse walls may extend, for example, from one of the webs to another of the webs. For example, the transverse walls may be arranged perpendicularly to the webs. For example, the transverse walls may have a lesser height than the spacers, for example, if the spacing between substrate and the jacket of the processing head is implemented with the aid of the spacers and/or the overpressure in the processing chamber or chambers or the partial vacuum on the side of the substrate facing away from the processing chamber or chambers. For example, the transverse walls may, with the webs, with the radial outer edge of the processing head, for example, the jacket surface, and with the substrate, form, enclose, and/or delimit from one another individual processing chambers. In this case, the delimitation may be more or less discrete depending on the height of the transverse walls. For example, a gas inlet for suctioning out process gas may be arranged before and/or after each transverse wall. In this way, segmented processing chambers may be formed on the outer circumference, in which different pressures may be generated successively and, for example, different process gases may be supplied or suctioned out. For example, between each two transverse walls, one gas outlet may be implemented in each case for supplying one process gas in each case to the corresponding processing chamber.

Alternatively thereto, the transverse walls may be omitted, so that the delimitation of the processing chambers is no longer discrete, but rather the processing chambers continuously merge into one another. Mixing and/or entraining of the process gases over individual processing chambers may be set via the partial pressures of the process gases in the processing chambers, in particular reduced or prevented. The supply of the flushing gas between the reaction gases may also contribute to preventing the entrainment of the reaction gases, for example. If no transverse walls are provided or the transverse walls only have a low height in comparison to the spacers, the processing chambers thus merge into one another and are essentially characterized by the process gases located therein during operation. In other words, the process gases form gas cushions, which rotate with the processing head and move over the substrate at the rotational velocity of the processing head. The gas cushions define the processing chambers. The volumes and shapes of the gas cushions and therefore of the processing chambers then vary in dependence on the rotational velocity of the processing head, the spacing between processing head and substrate, the viscosities of the process gases, and/or the flow parameters of the process gases, for example, in dependence on the flow densities, the differential pressures, and/or the partial pressures.

According to various embodiments, channels spaced apart from the radial outer edge are implemented in the processing head, which are used for the purpose of connecting the gas outlets or the gas inlets on the radial outer edge to a gas feedthrough, via which the gas outlets on the radial outer edge are supplied with process gas or via which the suctioned-off process gas is discharged. The channels may extend in the axial direction and/or in the radial direction. For example, the channels at the axial ends of the processing head may extend in the radial direction and/or the channels spaced apart from the axial ends of the processing head may extend in the axial direction.

According to various embodiments, the device includes a drive unit for rotating the processing head. The drive unit may have, for example, a motor, a gearing, for example, a gearwheel or a step-down gear. The drive unit may be integrated in the housing or may be arranged outside the housing and/or may engage on a rotating shaft of the processing head.

According to various embodiments, the device includes multiple processing heads arranged in series. The fact that the processing heads are arranged in series means in this context that the substrate successively passes through the individual processing heads, wherein the processing heads may be arranged so that the same side and/or the other side of the substrate is treated by the following processing head or heads. This may contribute in a simple manner to applying multiple identical or different layers successively to the substrate.

In various embodiments, a method for the surface treatment of a substrate is provided, in which the substrate is laid at least partially around the radial outer edge of the rotatably mounted processing head so that the surface of the flexible substrate faces toward the processing head, and the processing chamber is formed between the surface of the flexible substrate and the processing head. The processing head is rotated and at least one process gas for the treatment of the surface of the substrate facing toward the processing head is supplied to the processing chamber via the rotating processing head. The processing chamber rotates with the processing head.

According to various embodiments, the processing head is implemented and the flexible substrate is laid around the radial outer edge of the processing head so that the processing chamber, which is formed between the radial outer edge of the processing head and the substrate, is delimited by the processing head and the flexible substrate. For example, the processing chamber may be delimited by the radial outer edge, for example, the jacket surface, by one web in each case at the axial ends of the outer edge of the processing head, optionally by two of the transverse walls, and by the surface of the flexible substrate to be coated. By way of the supply and discharge of the process gas, for example, a mean pressure of, for example, 0.001 to 5 bar, for example, 0.01 to 2 bar, for example, 0.1 to 1.5 bar may be generated in the processing chamber. According to various embodiments, a process gas is discharged via the radial outer edge of the processing head, for example, one of the reaction gases and/or the flushing gas. For example, reaction gases may be successively discharged, which are not permitted to mix, for example, the gaseous educts in the case of an ALD process. Furthermore, the flushing gas may be discharged in the meantime. In this case, a partial vacuum or a differential pressure, for example, between 0.001 and 1 bar, for example, between 0.01 and 0.1 bar, for example, between 0.05 and 0.08 bar may be generated in the processing chamber, wherein the differential pressure relates, for example, to the pressure difference between two adjacent processing chambers.

According to various embodiments, a coating method is carried out with the aid of the processing head. The coating method may be, for example, a CVD process or an ALD process. Alternatively thereto, an ablation process may also be carried out with the aid of the processing head, for example, a dry etching process; for example, chemical dry etching may be carried out. For example, mono-atomic or multi-atomic layers may be applied, which may have a thickness from a few angstroms up to several nanometers. For example, 100 to 200 identical or different layers lying one on top of another may be applied to the substrate. The thickness of the respective layer is only dependent on how many revolutions the processing head completes over the region of the substrate to be coated, wherein the thickness grows with increasing number of the revolutions.

According to various embodiments, an ALD process is carried out.

According to various embodiments, firstly a first reaction gas, for example, a first gaseous educt, then a flushing gas, and then a second reaction gas, for example, a second gaseous educt are supplied successively via the rotating processing head. The reaction gases or the flushing gas may be supplied repeatedly in succession, for example, to generate multiple layer sequences. In addition, further gaseous educts may also be supplied, to generate different layers. Using the first gaseous educt, for example, the surface of the flexible substrate to be coated is saturated and the second gaseous educt accumulates on the layer of the first gaseous educt. A mono-atomic first layer thus results, in particular during one revolution of the processing head. In addition, by supplying further educts, one, two, or more further layers may be formed during a revolution of the processing head and/or further layers made of the same material or materials or material combinations or other materials or material combinations may be formed during following revolutions. This enables, for example, first ALD layers and second ALD layers to be applied alternately. Alternatively thereto, during multiple revolutions, only a first reaction gas may be supplied and subsequently during multiple further revolutions, a second reaction gas may be supplied. Furthermore, two reaction gases may be supplied in each case during multiple revolutions, and two further reaction gases may be supplied in each case during further multiple revolutions. This enables, for example, multiple layers of a first ALD layer and then multiple layers of a second ALD layer to be applied.

According to various embodiments, the feed of the substrate is stopped or is not stopped during the surface treatment. For example, the feed of the substrate may be cyclic, so that sequential oblong regions of the substrate are treated successively. During one cycle, multiple layers of identical or different materials or identical or different material combinations may be deposited on the substrate or removed therefrom. Alternatively thereto, the feed of the substrate may be performed continuously, for example, at a constant feed velocity. Multiple layers of identical or different materials or identical or different material combinations may also be deposited in this case on the flexible substrate or removed therefrom, for example, if a peripheral velocity of the processing head is greater than a feed velocity of the substrate.

According to various embodiments, a peripheral velocity of the processing head is greater than a feed velocity of the substrate. The feed velocity of the substrate may be, for example, during use of a processing head, in a range between 0 and 100 m/min, for example, between 0.1 and 10 m/min, for example, between 0.5 and 5 m/min. If multiple processing heads are used in succession, the feed velocity may be further increased with increasing number of processing heads. A rotational frequency of the processing head may be in a range between 1 and 1000 RPM, for example, between 100 and 500 RPM, for example, between 150 and 250 RPM. The peripheral velocity, in other words, the velocity at which a point on the radial outer edge of the processing head moves, is dependent on the rotational velocity and the radius of the processing head.

According to various embodiments, the substrate may be laid around the radial outer edge of one or more further processing heads and the surface of the substrate may be treated further accordingly using them. For example, a first side of the substrate may be coated using a first processing head and a second side of the substrate, which faces away from the first side, may be coated using a second processing head. Alternatively thereto, the same side of the substrate may be coated multiple times using two or more processing heads.

In various embodiments, a method for producing an optoelectronic component is provided, which includes the method described above and/or hereafter for the surface treatment of the substrate. For example, in this case the substrate is coated with an electrode layer, an optical functional layer, an organic functional layer, a barrier layer, and/or an encapsulation layer. For example, the substrate may be a film. For example, the encapsulation layer may be substantially impermeable to water vapor and/or gases. Furthermore, the optical functional layer may be, for example, a (high) refraction layer, for example, a highly refractive layer, a scattering layer, or a converter layer for converting light. Furthermore, structures may already be formed on the substrate, which become coated. For example, a stack of layers and/or, for example, a layer packet may already be formed on the substrate.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a schematic view of an embodiment of a device for the surface treatment of a substrate;

FIG. 2 shows a sectional view through an embodiment of a device for the surface treatment of a substrate perpendicular to an axis of rotation of a processing head of the device;

FIG. 3 shows a perspective view of the embodiment of the device for the surface treatment of a substrate according to FIG. 2;

FIG. 4 shows a section through the embodiment of the device for the surface treatment of a substrate according to

FIG. 2 along the axis of rotation of the processing head of the device;

FIG. 5 shows a side view of a gas guide of the device according to FIG. 2;

FIG. 6 shows a section through the gas guide according to FIG. 5;

FIG. 7 shows a schematic side view of an exemplary processing head of a device for the surface treatment of a substrate;

FIG. 8 shows a first exemplary layer structure;

FIG. 9 shows a second exemplary layer structure;

FIG. 10 shows a third exemplary layer structure;

FIG. 11 shows a flow chart of an embodiment of a method for the surface treatment of a substrate;

FIG. 12 shows a flow chart of a further embodiment of a method for the surface treatment of a substrate;

FIG. 13 shows an embodiment of a device for the surface treatment of a substrate;

FIG. 14 shows a further embodiment of a device for the surface treatment of a substrate;

FIG. 15 shows an embodiment of a processing head in a side view;

FIG. 16 shows a further embodiment of a processing head in a side view; and

FIG. 17 shows a diagram to illustrate a functional principle of a device for the surface treatment of a substrate and entrainment of process gases.

### DETAILED DESCRIPTION

In the following detailed description, reference is made to the appended drawings, which form a part of this description and in which specific embodiments, in which the disclosure can be implemented, are shown for illustration. In this regard, direction terminology such as “top”, “bottom”, “forward”, “back”, “front”, “rear”, etc. is used with reference to the orientation of the described figure(s). Since components of embodiments can be positioned in a number of different orientations, the direction terminology is used for illustration and is in no way restrictive. It is obvious that other embodiments can be used and structural or logical changes can be performed without deviating from the scope of protection of the present disclosure. It is obvious that the features of the different embodiments described herein can be combined with one another, if not specifically indicated otherwise. The following detailed description is therefore not to be interpreted in a restrictive sense, and the scope of protection of the present disclosure is defined by the appended claims.

In the scope of this description, the terms “connected”, “attached”, and also “coupled” are used to describe both a direct and also an indirect connection, a direct or indirect attachment, and also a direct or indirect coupling. In the figures, identical or similar components are provided with identical reference signs, insofar as this is expedient.

An optoelectronic component may be a light-emitting component or a light-absorbing component. A light-emitting component may be understood in various embodiments as an organic light-emitting diode (OLED), a light-emitting electrochemical cell (LEC), or an organic light-emitting transistor. The light-emitting component may be part of an integrated circuit according to various embodiments.

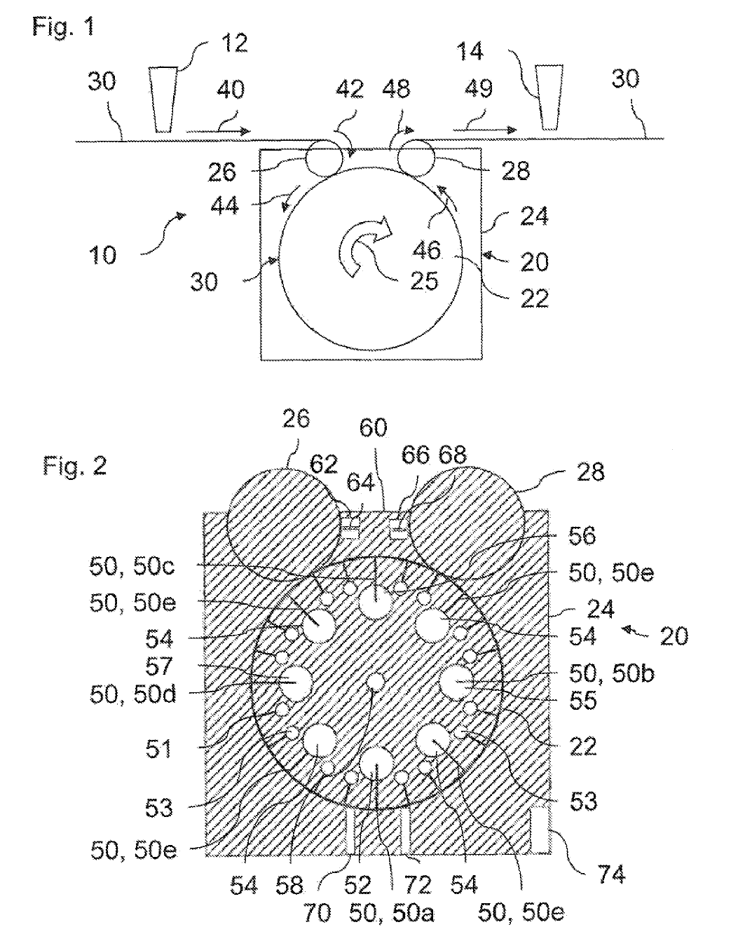

FIG. 1 shows a schematic view of an embodiment of a device 10 for the surface treatment of a substrate 30. The device 10 may optionally include a first processing stage 12 and/or a second processing stage 14. The device 10 furthermore includes a processing unit 20, which includes a processing head 22, which is rotatably mounted in a housing 24 in a rotation direction 25. The housing 24 enables, for example, an environment of the processing unit 20 to be protected from process gases, processing regions in the housing 24 to be controlled in temperature, and/or the substrate 30 to be protected.

The substrate 30 includes, for example, a Kapton film (PI), a metal film, or a PET film. For example, the substrate 30 may include or be formed from a steel film, a plastic film, or a laminate having one or more plastic films. The plastic may include or be formed from one or more polyolefins (for example, polyethylene (PE) having high or low density or polypropylene (PP)). Furthermore, the plastic may include or be formed from polyvinyl chloride (PVC), polystyrene (PS), polyester, and/or polycarbonate (PC), polyethylene terephthalate (PET), polyether sulfone (PES), PEEK, PTFE, and/or polyethylene naphthalate (PEN). The substrate 30 may include one or more of the above-mentioned materials.

The device 10 furthermore includes a feed device, which has a first roller 26 and a second roller 28, for example. The axes of rotation of the rollers 26, 28 may be implemented in parallel to the axis of rotation 58 of the processing head 22, for example.

The processing unit 20, the processing head 22, and the feed device may be implemented, for example, so that the substrate 30, which is a flexible substrate, for example, may be supplied to the processing unit 20, may be guided around the processing head 22, and may be guided via the second roller 28 out of the processing unit 20. During the feed process, the substrate 30 moves along a first direction 40 toward the first roller 26 and is laid along a second direction 42 around the first roller 26, so that it comes into contact with a radial outer edge of the processing head 22. The substrate is laid along a third direction 44 and a fourth direction 46 around the processing head 22 up to the second roller 28. On the second roller 28, the substrate 30 bends in a fifth direction 48, is thus guided out of the processing unit 20, and runs further along a sixth direction 49.

The substrate 30 may thus be arranged on the radial outer edge of the processing head 22 and, in the case of the flexible substrate, at least partially around the radial outer edge of the processing head 22. The surface of the substrate 30 facing toward the processing head 22 may thus be treated with the aid of the processing head 22. This enables the substrate 30 to be gradually fed past the radial outer edge of the processing head 22 in a substrate formation, for example, as an endless substrate, for example, as an endless film, and the endless substrate to be treated in this case. This enables the treatment of the surface of the substrate 30 to be carried out in a roll-to-roll process, without having to separate the substrate 30. For example, the flexible substrate 30 may be coated in the roll-to-roll process, for example, in a CVD process, for example, in an ALD process.

The device 10 and in particular the processing unit 20 are used for the purpose of treating, for example, coating, a surface of the substrate 30. Alternatively thereto, a surface layer on the substrate 30 may be ablated with the aid of the processing unit 20. The substrate 30 may, for example, be unrolled on a left side of the device 10 in FIG. 1 from a roll (not shown), its surface may be treated with the aid of the processing unit 20, and the treated substrate 30 may be rolled onto a further roll (not shown) on a right side of the device 10 in FIG. 1. The substrate 30 may then be unrolled again and separated. Alternatively thereto, the substrate 30 may be separated directly after the surface treatment. The substrate 30 which is not yet separated may also be referred to as a substrate formation. The substrate 30 may already be coated, for example, with an organic functional layer structure for emitting or absorbing light and/or with one or more electrode layers. For example, the substrate 30 may optionally be coated with the aid of the optionally arranged first processing stage 12 and/or the second processing stage 14.

FIG. 2 shows an enlarged sectional view of the embodiments of the processing unit 20 having the processing head 22 shown in FIG. 1. The processing head 22 is rotatably mounted about an axis of rotation 58. The processing head 22 is implemented as cylindrical and has an axis and a jacket surface, which is implemented on the radial outer edge of the processing head 22, wherein the axis lies on the axis of rotation 58. For example, the processing head may essentially form a right cylinder, the axis of which extends from a center point of its cover surface to the center point of its base surface. In other words, the processing head 22 may be implemented as drum-shaped. The processing head 22 includes multiple gas inlets 51 and multiple gas outlets 50, which are implemented on the radial outer edge, for example, on the jacket surface, of the processing head 22. The gas outlets 50 are implemented and arranged so that in operation, a process gas leaves at least one of the gas outlets 50 in a direction having a radially oriented directional component. In the axial direction, the processing head 22 may be, for example, between 1 mm and 10 000 mm, for example, between 10 mm and 1000 mm, for example, between 100 mm and 500 mm wide, in dependence on the width of the substrate 30 to be treated, for example. The radius of the processing head 22 may be, for example, between 10 mm and 1000 mm, for example, between 100 mm and 600 mm.

The gas outlets 50 on the radial outer edge enable a surface treatment of the substrate 30 with a low gas consumption and a high processing velocity, in particular if multiple reaction gases are required successively per step and/or if multiple identical or different layers must be applied or ablated one on top of another. Furthermore, the processing unit 20 may be implemented very compactly and may therefore be incorporated easily in an existing production line.

In various embodiments, a process gas may be blown out of the processing head 22 in the radial direction, for example, i.e., perpendicularly to the axis of rotation 58. Alternatively thereto, the process gas may be blown out of the processing head 22 only partially oriented in the radial direction, for example, in consideration of a flow optimization in the case of rotating processing head 22.

The gas outlets 50 and/or the gas inlets 51 on the jacket surface may be implemented as slotted. For example, the gas outlets 50 may each be implemented by one slot (see FIG. 15), which extends transversely over the jacket surface in the axial direction, for example, parallel to the axis of rotation 58 and/or from one axial end of the processing head 22 to the other axial end of the processing head 22, and which extends in the radial direction from the outer circumference of the processing head 22 into the processing head 22 toward multiple channels 52, 54, 55, 56, 57, which are spaced apart from the radial outer edge of the processing head 22, and which are used for the purpose of connecting the gas outlets 50 for supplying or the gas outlets 51 for discharging the process gases to gas feedthroughs described hereafter. The slotted implementation of the gas outlets 50 contributes to the substrate 30 arranged around the outer edge being uniformly coated. Alternatively thereto, the gas outlets 50 may be implemented as circular or polygonal (see FIG. 16). Alternatively thereto, one, two, or more slotted or circular outlets may jointly form one of the gas outlets 50.

For example, the processing head 22 may have multiple gas outlets 50, which include a first gas outlet 50a, which communicates with a first channel 52, for supplying a first reaction gas, and/or include a second gas outlet 50b, which communicates with a second channel 55, for supplying a second reaction gas. Furthermore, the processing head 22 may include a third gas outlet 50c, which communicates with a third channel 56, for supplying the first reaction gas or for supplying a third reaction gas, and/or may include a fourth gas outlet 50d, which communicates with a fourth channel 57, for supplying the second reaction gas or a fourth reaction gas, and/or may include one or more further or fifth gas outlets 50e, which communicate or communicates with one or more fifth channels 54, for supplying a flushing gas as a further or fifth process gas.

The gas outlets 50a, 50b, 50c, 50d, 50e enable, for example, three different process gases to be supplied, for example, in an ALD process, as a first process gas, a first gaseous educt and, as a second process gas, a second gaseous educt for producing a material layer of a first material or a first material combination, and a flushing gas for carrying out flushing (purge) as a further process gas. In the case of the ALD process, the first and second gaseous educts are also referred to as the first and second precursors, respectively. In addition, two further process gases may be supplied, for example, as a third process gas, a third precursor, and as a fourth process gas, a fourth precursor for producing a material layer of a second material or a second material combination. In addition, still further gas outlets may be provided, for example, two further educts may be supplied or multiple gas outlets may also be provided for one of the process gases.

In each case one or two of the gas inlets 51 may be implemented on the outer edge of the processing head 22 between the gas outlets 50 on the outer edge of the processing head 22. The gas inlets 51 may be implemented as slotted and/or circular, corresponding to the gas outlets 50, and may extend in the axial direction transversely over the jacket surface, for example, parallel to the axis of rotation 58 and/or from one axial end of the processing head 22 to the other axial end of the processing head 22, and may extend in the radial direction from the outer circumference of the processing head 22 into the processing head 22 toward multiple corresponding channels 53, which are spaced apart from the radial outer edge of the processing head 22, and which are used for the purpose of connecting the gas inlets 51 on the outer edge of the processing head 22 to gas feedthroughs described hereafter.

In various embodiments, for example, one fifth gas outlet 50e for the flushing gas may always be provided in each case between two gas outlets 50a, 50b, 50c, 50d for the educts. Furthermore, one gas inlet 51 for suctioning out the educts or the flushing gas may be provided in each case between the gas outlets 50a, 50b, 50c, 50d of the educts. Thus, for example, along the circumference of the radial outer edge, successively a first gas outlet 50a for the first educt, a gas inlet 51 for suctioning out the first educt, a fifth gas outlet 50e for the flushing gas 50e, a further gas inlet 51 for suctioning out the flushing gas, a second gas outlet 50b for the second educt, a further gas inlet 51 for suctioning out the second educt, a further fifth gas outlet 50e for the flushing gas, and a further gas inlet 51 for suctioning out the flushing gas may be provided. This sequence may be repeated multiple times, and/or still further gas outlets 50 may be provided for further educts.

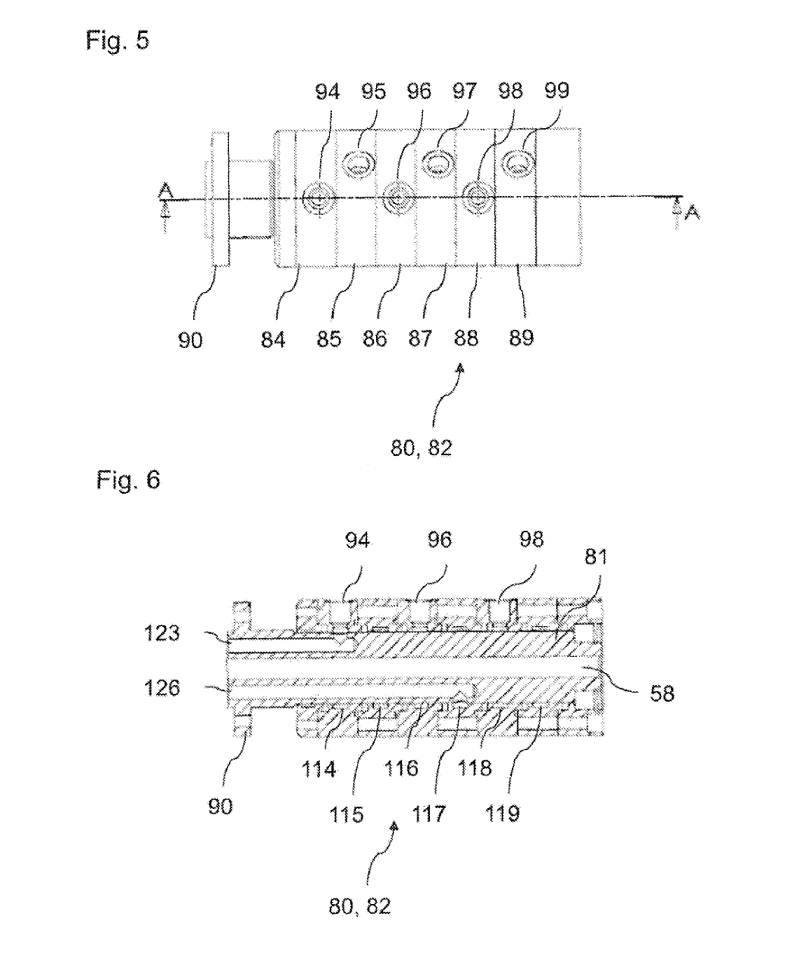

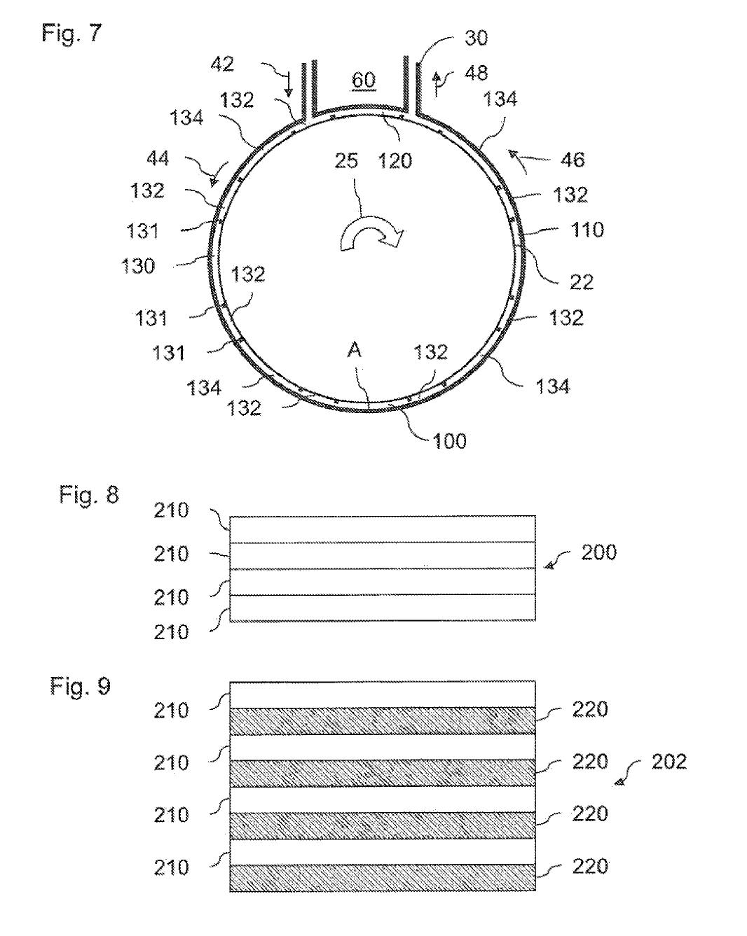

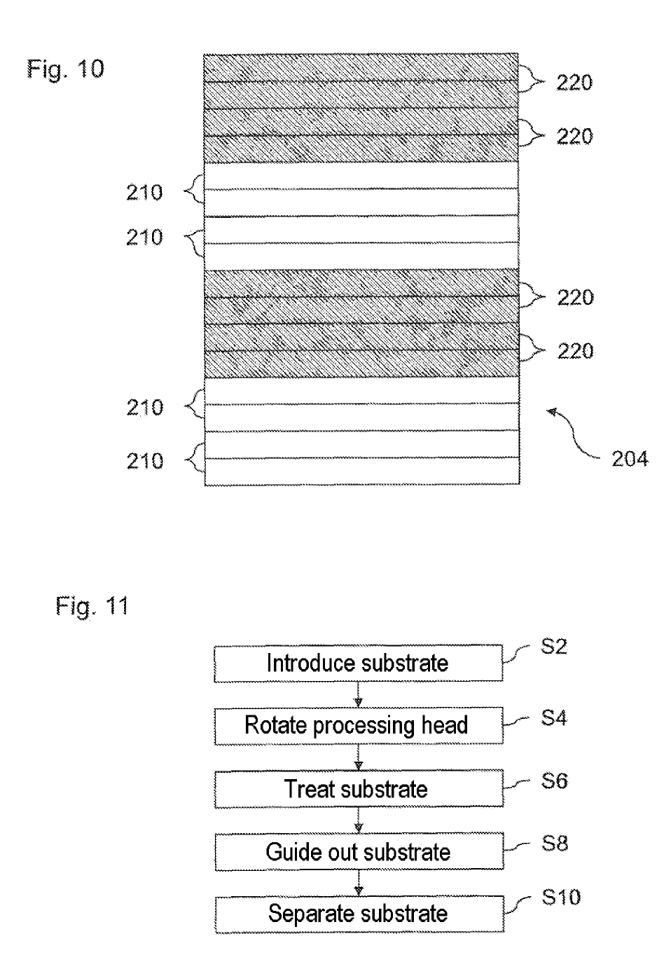

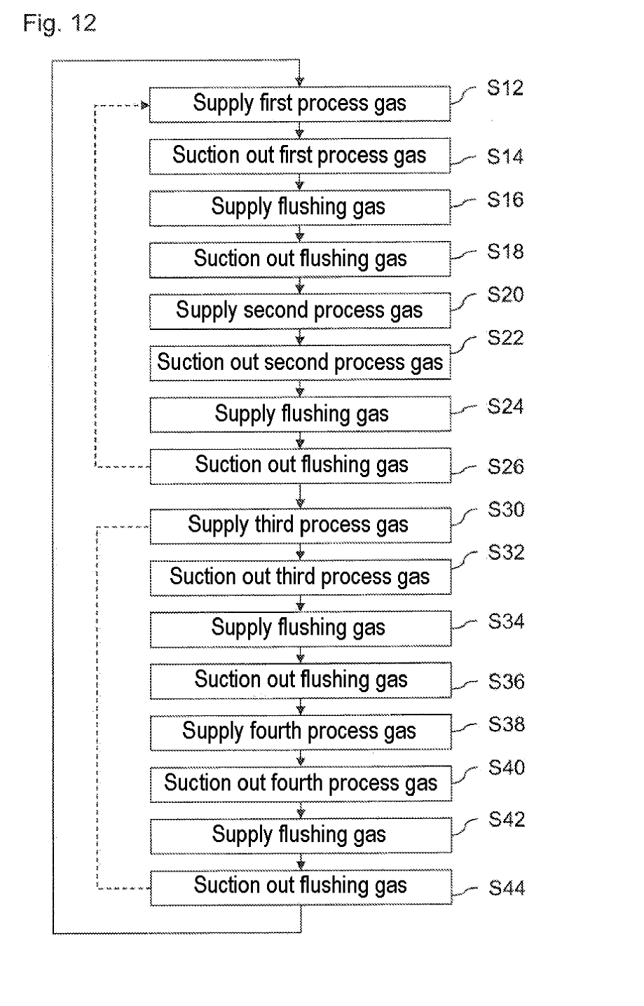

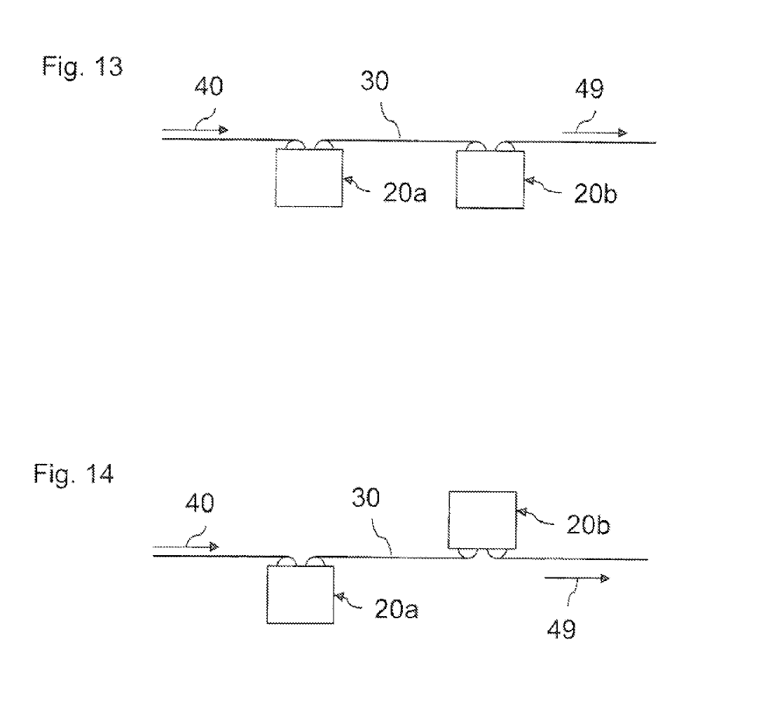

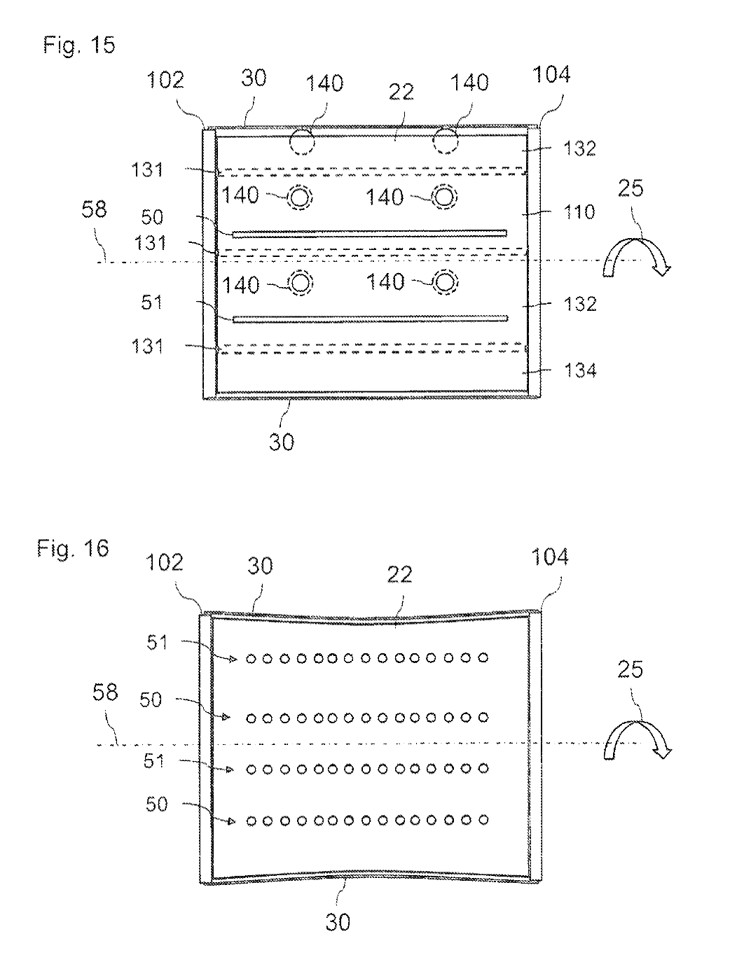

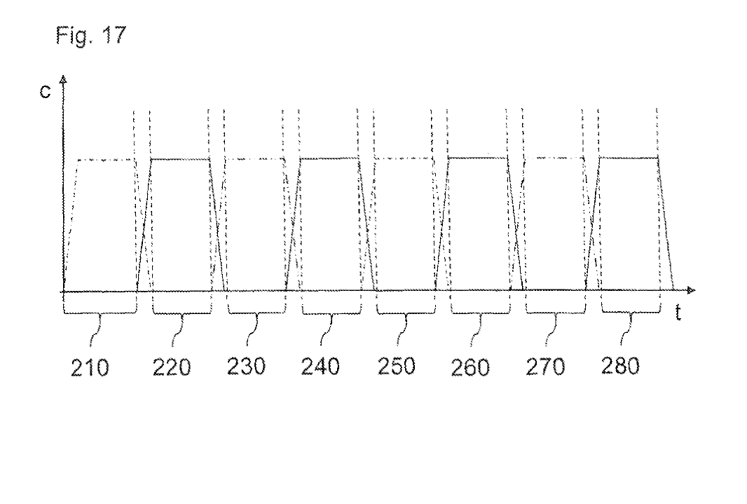

The channels 52, 53, 54, 55, 56, 57 may extend in the axial and/or radial directions through the processing head 22. For example, the channels 52, 53, 54, 55, 56, 57 may extend in the radial direction on the axial ends of the processing head 22, in other words on the base surface and/or the cover surface of the cylinder shape, and may extend in the axial direction spaced apart from the axial ends of the processing head 22. Alternatively to the radially extending parts of the channels 52, 53, 54, 55, 56, 57, frontal bodies 101, 103 (see FIG. 4) may be arranged, which are coupled to the processing head 22 and which accommodate the radial parts of the channels 52, 53, 54, 55, 56, 57 and thus connect the axially extending channels 52, 53, 54, 55, 56, 57 to the gas feedthroughs described hereafter.

In the region of the feed device having the first roller 26 and the second roller 28, for example, between the first roller 26 and the second roller 28, an adapter 60, a first housing suction unit 62 for suctioning out process gas from the housing 24, a first housing flushing gas supply 64 for supplying flushing gas into the housing 24, a second housing suction unit 66 for suctioning gas out of the housing 24, and/or a second housing flushing gas supply 68 for supplying flushing gas into the housing 24 may be implemented, which face toward the surface of the substrate 30 to be treated, for example. In addition, still further suction units 62, 66 may be arranged. The further suction units 62, 66 may be arranged, for example, successively from the outside to the inside or from the inside to the outside, for example, sequentially to the outside, so that according to the principle of differential pumping, the penetration of ambient air into the housing 24 and/or the escape of process gases out of the housing 24 is prevented. Furthermore, a suction unit may be arranged in the housing 24 so that the substrate 30 is suctioned into the housing 24 away from the processing head 22, whereby a spacing between the jacket surface of the processing head 22 and the substrate 30 is predefined.

Alternatively or additionally, a third housing flushing gas supply 70 for supplying flushing gas into the housing 24 and/or a third housing suction unit 72 for suctioning gas out of the housing 24 may be implemented, which are spaced apart from the feed device, for example, and/or which may be arranged on a side of the substrate 30 facing away from the surface of the substrate 30 to be treated, for example. For example, the third housing suction unit 72 may contribute to suctioning the substrate 30 away from the processing head 22 and/or predefining the spacing between the substrate 30 and the jacket surface of the processing head 22.

The flushing gas may thus be supplied, for example, onto the surface of the substrate 30 to be coated, for example, in the region of the feed device, for example, between the rollers 26, 28, and/or onto the surface of the substrate 30 not to be coated, for example, spaced apart from the feed device.

A heating device 74 may be arranged in the housing 24, using which an interior of the housing 24 may be heated. Alternatively or additionally, the housing 24 may be heated with the aid of heated flushing gas. Alternatively or additionally, the processing head 22 may be heated. A temperature in the housing 14 may be between 0° and 1000° C., for example, between 20° and 500° C., for example, between 150° and 250° C., for example, may be approximately 200° C.

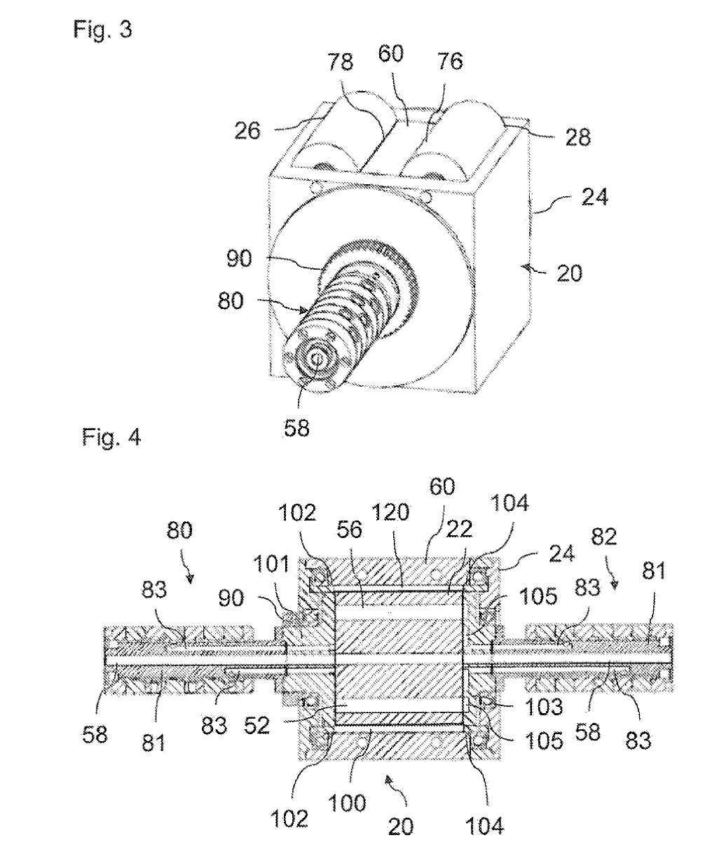

FIG. 3 shows that the housing 24 may have a supply opening 78 for supplying the substrate 30 and a discharge opening 76 for discharging the substrate 30. Furthermore, the processing unit 20 may have a drive unit 90 for rotating the processing head 22. The drive unit 90 may have, for example, a motor, a gearing, for example, a gearwheel or a step-down gear. The drive unit may be integrated in the housing 24, or may engage outside the housing 24 on a rotating shaft, which lies on the axis of rotation 58, of the processing head 22.

For example, one or two rotating feedthroughs 80, 82 (see FIG. 4) may be provided for supplying and discharging the process gases to or from, respectively, the processing head 22.

FIG. 4 shows a section through the processing unit 20 and through a first rotating feedthrough 80 and a second rotating feedthrough 82. The rotating feedthroughs 80, 82 each have a rotatable inner body 81, which are rotatable about the axis of rotation 58. For example, the inner bodies 81 may be fastened on the same rotating shaft as the processing head 22 or the rotating feedthroughs 80, 82 may have separate rotating shafts, which are mechanically coupled to the rotating shaft of the processing head 22. The inner body 81 has multiple axially extending cavities 83, which are implemented for supplying or discharging process gases, and which may also be referred to as gas feedthroughs and will be explained in greater detail hereafter with reference to FIG. 6.

FIG. 4 furthermore shows that the channels 52, 53, 54, 55, 56, 57, for example, the channels 52, 56, extend in the axial direction through the processing head 22, and the processing head 22 is mechanically coupled in the axial direction to a first frontal body 101 and to a second frontal body 103, wherein the two frontal bodies 101, 103 mechanically couple the processing head 22 to the first or second rotating feedthrough 80, 82, respectively. The frontal bodies 101, 103 may have recesses 105, for example, which extend at least partially in the radial direction and via which the cavities 83 of the rotating feedthroughs 80, 82, i.e., via the gas feedthroughs, may communicate with the channels 52, 53, 54, 55, 56, 57. In other words, the recesses 105 form radial parts of the channels 52, 53, 54, 55, 56, 57. Alternatively or additionally, recesses (not shown) may be implemented, for example, on or in the case of frontal faces of the processing head 22, in other words on the base surface and/or the cover surface of the cylinder shape of the processing head 22, which form the radial parts of the channels 52, 53, 54, 55, 56, 57, and via which the cavities 83 of the rotating feedthroughs 80, 82 may communicate with the channels 52, 53, 54, 55, 56, 57.

To arrange the substrate 30 around the processing head 22, the device 10 may include a web 102, 104 in each case adjacent to the axial outer ends of the radial outer edge of the processing head 22, each web protruding in the radial direction from the jacket of the processing head 22 and extending, for example, around the entire circumference or sections of the circumference of the processing head 22. The webs 102, 104 are used as spacers for predefining the spacing between the jacket surface of the processing head 22 and the substrate 30. Alternatively or additionally to the webs 102, 104, further spacers 140 may be provided (see FIG. 15). In operation of the processing unit 20, the substrate 30 may be guided at least partially around the processing head 30 so that it rests on its lateral edges, which are not to be coated, of the surface to be coated on the webs 102, 104. The surface of the substrate 30 to be coated, the jacket surface of the processing head 22, and the webs 102, 104 then delimit one or more processing chambers, for example, a first processing chamber 100 and a third processing chamber 120, to which the process gases are supplied in operation for the treatment of the surface of the substrate 20. The webs 102, 104 protrude, for example, between 0.01 and 10 mm, for example, between 0.05 and 5 mm, for example, between 0.1 and 1 mm from the radial outer edge of the processing head 22 in the radial direction, so that the processing chambers with the substrate 30 applied have a height between 0.01 and 10 mm, for example, between 0.05 and 5 mm, for example, between 0.1 and 1 mm. The webs 102, 104 may have, for example, a width between 1 and 20 mm, for example, between 5 and 15 mm. The gas outlets 50 and gas inlets 51 are implemented between the webs 102, 104, for example. The processing chambers 100, 120 are defined and/or characterized by the volume, in which a specific process gas is located and/or to which a predefined process gas is to be supplied or in which one or two process gases are to be discharged. The processing chambers 100, 120 rotate with the processing head 22 and move over the substrate surface to be coated.

In addition, one, two, or more further corresponding webs may be arranged between the webs 102, 104, on which the substrate may additionally be laid, for example, to prevent the substrate 30 from sagging, whereby the processing chambers would be reduced in size. The arrangement of the further webs may be performed, for example, in dependence on the axial length of the processing head 22, the width, and/or the stability of the substrate 30 to be treated.

Furthermore, in addition to the webs 102, 104, fixing elements (not shown) may be provided, which are used to fix the substrate 30 during its revolution around the processing head 22 in the third and fourth directions 44, 46 on the webs 102, 104. For example, the webs 102, 104 may include pins and the substrate 30 may include holes corresponding to the pins, so that the pins engage in the holes and the substrate 30 is fixed during the feed in relation to the rotatably mounted webs 102, 104 and is rotated with the webs 102, 104 or also rotates these webs, as is known from printers equipped with endless paper having holes. Alternatively thereto, the fixing elements may also include one or more clamping devices, with the aid of which the substrate 30 may be fixedly clamped and/or clamped in the axial direction, for example, automatically fixedly clamped.

FIG. 5 shows an example of one of the rotating feedthroughs 80, 82 from the outside in a side view. The illustrated rotating feedthrough 80, 82 is divided in the axial direction into multiple segments, for example, into a first segment 84, a second segment 85, a third segment 86, a fourth segment 87, a fifth segment 88, and/or a sixth segment 89. The segments 84 to 89 may include multiple attachment openings. The segments 84 to 89 may consist of a single part or multiple mechanically coupled single parts. For example, a first attachment opening may be implemented on the first segment 84, a second attachment opening 95 on the second segment 85, a third attachment opening 96 on the third segment 86, a fourth attachment opening 97 on the fourth segment 87, a fifth attachment opening 98 on the fifth segment 88, and/or a sixth attachment opening 99 on the sixth segment 89.

The inner body 81 may be rotated in relation to the segments 84 to 89, so that the segments 84 to 89 may remain stationary during the operation of the processing unit 20 and therefore during a rotation of the processing head 22 and the inner body 81. This enables the attachment openings 94 to 99 for supplying or discharging the process gases to be connected to stationary gas lines (not shown), via which the process gases may be supplied to the processing head 22 or discharged therefrom.

FIG. 6 shows a section through the illustrated rotating feedthrough 80, 82 according to FIG. 5 along section line A-A shown therein. The segments 84 to 89 include multiple internal grooves, via which the attachment openings 94 to 99 communicate with the cavities 83 (see FIG. 4), wherein the cavities 83 include, for example, a first gas feedthrough 123 and/or a fourth gas feedthrough 126. For example, the first segment 84 includes a first internal groove 114, via which the first attachment opening 94 communicates with the first gas feedthrough 123, the second segment 85 includes a second internal groove 115, via which the second attachment opening 95 communicates with a second gas feedthrough (not shown), the third segment 86 includes a third internal groove 116, via which the third attachment opening 96 communicates with a third gas feedthrough (not shown), the fourth segment 87 includes a fourth internal groove 117, via which the fourth attachment opening 97 communicates with the fourth gas feedthrough 126, the fifth segment 88 includes a fifth internal groove 118, via which the fifth attachment opening 98 communicates with a fifth gas feedthrough (not shown), and/or the sixth segment 89 includes a sixth internal groove 119, via which the sixth attachment opening 99 communicates with a sixth gas feedthrough (not shown).

The internal grooves 114 to 119 cause process gases to be able to be supplied permanently to the processing head 22 or discharged from the processing head 22 via the attachment openings 94 to 99 and the gas feedthroughs 123, 126 even if inner body 81 is rotating.

FIG. 7 shows a schematic side view of the processing head 22, wherein for better explanation, the webs 102, 104 are not shown and the substrate 30 is guided around the processing head 22. On the radial outer edge of the processing head 22, for example, on its jacket surface, for example, multiple transverse walls 131 may be implemented, which divide the circumference of the processing head 22 into multiple segments. The transverse walls 131 may protrude in the radial direction from the jacket surface and may extend in one direction having a directional component in the axial direction, i.e., may be applied tangentially to the jacket surface. For example, the transverse walls 131 may extend in the axial direction from the web 102 up to the web 104 and/or may be perpendicular to the webs 102, 104, for example. The transverse walls 131 may have a lesser height than the webs 102, 104, for example. For example, the transverse walls 131, with the webs 102, 104, with the jacket surface of the processing head 22, and with the surface of the substrate 30 to be treated, may more or less delimit individual processing chambers 100, 120 from one another. In this manner, segmented processing chambers 100, 120 may be formed on the external circumference, in which different pressures may be successively generated and, for example, different process gases may be supplied or suctioned out. For example, the first processing chamber 100, a second processing chamber 110, the third processing chamber 120, and/or a fourth processing chamber 130 may thus be implemented. Further processing chambers may be formed between the processing chambers 100, 110, 120, 130, for example, one, two, or more fifth processing chambers 134 and/or one, two, or more sixth processing chambers 132.

A first, a second, a third, and a fourth reaction gas, respectively, for treating the surface of the substrate 30 may be supplied, for example, to the first to fourth processing chambers 100, 110, 120, 130 via the first to fourth gas inlets 50a, 50b, 50c, 50d. Alternatively thereto, for example, only one or two reaction gases alternately may be supplied to the first to fourth processing chambers 100, 110, 120, 130. A flushing gas may be supplied to the fifth processing chambers 134, for example, via the fifth gas inlets 50e as a fifth or further process gas. The fifth processing chambers 134 may also be referred to in this context as flushing regions. In the sixth processing chambers 132, a partial vacuum may be permanently generated via the gas inlets 51, for example, or at least a lower pressure than in the preceding processing chamber may be generated, so that the previously supplied process gases may be suctioned out in the sixth processing chambers 132. The sixth processing chambers 132 may also be referred to in this context as partial vacuum regions. For example, close to the transverse walls 131, which delimit the sixth processing chambers 132, one gas inlet 51 for suctioning out process gas may be arranged inside each of the sixth processing chambers 132.

A region of the substrate 30, in which a predefined position A on the substrate is arranged, adjoins the first processing chamber 100. Therefore, in the situation shown in FIG. 7, for example, the first reaction gas in the first processing chamber 100 acts on the predefined position A of the substrate. At a later point in time, the region of the substrate 30 having the predefined position A adjoins another of the processing chambers, so that another process gas is incident on the predefined position A.

FIG. 8 shows an embodiment of a first layer structure 200, which is produced during the treatment of the surface of the substrate 30 and using which the surface of the substrate 30 is coated. The first layer structure 200 includes multiple first layers 210, for example, which each consist of the same first material or of the same first material combination. For example, each first layer 210 forms a complete ALD layer, which results, for example, from the reaction of two educts and/or which is formed, for example, during a single revolution of the processing head 22.

FIG. 9 shows an embodiment of a second layer structure 202, which is produced during the treatment of the surface of the substrate 30 and using which the surface of the substrate 30 is coated. The second layer structure 202 includes, for example, multiple first layers 210, which each consist of the first material or of the first material combination, and multiple second layers 220, which each consist of a second material or of a second material combination. The first and second layers 210, 220 are arranged alternately and in turns in succession. For example, each second layer 220 forms a complete ALD layer, which results, for example, from the reaction of a further educt with a previous educt or from the reaction of two further educts and/or which is formed, for example, during a single revolution of the processing head 22.

FIG. 10 shows an embodiment of a third layer structure 204, which is produced during the treatment of the surface of the substrate 30 and using which the surface of the substrate 30 is coated. The third layer structure 204 includes, for example, multiple ones of the first layers 210, which each consist of the first material or of the first material combination, and multiple ones of the second layers 220, which each consist of the second material or of the second material combination. In the third layer structure 204, multiple ones of the first layers 210, which form a first layer packet, and multiple ones of the second layers 220, which form a second layer packet, are arranged successively, wherein multiple ones of these layer packets are arranged alternately and in turns in succession. Alternatively or additionally to the above-described layer structures 200, 202, 204, further layer structures 200, 202, 204 are conceivable, which have, for example, layer structures having more or fewer layers and/or having more or fewer different layers, i.e., having different materials.

The mode of operation of the device 10 for the treatment of the surface of the substrate 30 and the production of the layer structures 200, 202, 204 are explained in greater detail hereafter in conjunction with a method for the treatment of the surface of the substrate 30, wherein the method may be carried out, for example, with the aid of the above-explained device 10 or using an alternative device. The layer structures 200, 202, 204 are produced during the method for the treatment of the surface of the substrate 30, which contributes, for example, to producing the optoelectronic component, which has the substrate 30 having one of the layer structures 200, 202, 204.

FIG. 11 shows a flow chart of an embodiment of an exemplary method for the treatment of the surface of the substrate 30. The method may be carried out, for example, with the aid of the above-described device 10.

In a step S2, the substrate 30 may be introduced into the device 10, for example, into the processing unit 20. The introduction of the substrate 30 into the processing unit 20 may be performed, for example, via the supply opening 78 such that the substrate 30 is first fed or displaced between the first roller 28 and the adapter 60, then between the processing head 22 and the first roller 28, and then between the processing head 22 and an inner wall of the housing 24. In this case, the substrate 30 is thus at least partially laid around the jacket surface of the processing head 22 and optionally on the webs 102, 104, so that a surface of the substrate 30 to be coated, which faces toward the processing head 22, and the jacket surface of the processing head 22 and optionally the webs 102, 104 and optionally the transverse walls 131 form the processing chambers 100, 110, 120, 130, 132, 134.

### Flushing Gas, for Example, Inert Gas

In a step S4, the processing head 22 is rotated. For example, a rotational frequency of the processing head 22 may be in a range between 1 and 1000 RPM, for example, between 100 and 500 RPM, for example, between 150 and 250 RPM or can be 200 RPM. Furthermore, the processing head 22 may be rotated in the rotation direction 25, which is opposite to the feed direction of the substrate 30, or opposes the rotation direction 25.

In a step S6, the surface of the substrate 30 is treated. For example, the surface of the substrate 30 may be at least partially ablated or the surface of the substrate 30 may be coated. For example, for coating or ablating the surface of the substrate 30, one, two, or more process gases may be supplied to the processing chambers 100, 110, 120, 130, 132, 134 or discharged therefrom via the rotating processing head 22. By way of the supply and discharge of the process gases, for example, pressures of 0.001 to 5 bar, for example, of 0.01 to 2 bar, for example, of 0.1 to 1.5 bar may be generated in the corresponding processing chambers. During the discharge of the process gases, for example, pressures of 0.0005 to 4.95 bar, for example, of 0.005 to 1.95 bar, for example, of 0.01 to 1.45 bar may be generated in the sixth processing chambers 132. The mentioned pressure specifications relate to absolute pressures. The differential pressures between the individual processing chambers may also be decisive, however, for an effective reduction or prevention of mixing and/or entrainment of the process gases and/or an effective supply or discharge of the process gases to or from, respectively, the processing chamber or chambers. For example, if the processing chambers are not discretely separated from one another, but rather more or less merge continuously into one another. Such a differential pressure may be, for example, between 0.001 and 1 bar, for example, between 0.01 and 0.1 bar, for example, between 0.05 and 0.08 bar. A differential pressure may also be, for example, a pressure difference between two pressures at a predefined position, for example, at the predefined position A, on the substrate 30 at different points in time. If the ablation process is carried out, this may be a dry etching process, for example, chemical dry etching, for example.

In a step S8, the substrate 30 may be guided out of the processing unit 20. In this case, the substrate 30 is firstly guided between the processing head 22 and the second roller 28, then between the second roller 28 and the adapter 60, and then via the discharge opening 76 out of the housing 24.

The supply and the discharge of the substrate 30 are performed, for example, without the substrate 30 being separated, whereby a roll-to-roll process is possible. The supply and the discharge of the substrate 30 into or out of the housing 24, respectively, may be performed continuously or in cycles in this case. For example, the feed of the substrate 30 may be interrupted or not interrupted during the surface treatment. For example, the feed of the substrate 30 may be cyclic, so that successive oblong regions of the substrate 30 are treated in succession. During one cycle, by supplying the process gases and during coating by deposition of the corresponding atoms and/or molecules, multiple layers of identical or different materials or identical or different material combinations may be deposited on the substrate 30 or, during ablation, removed therefrom. Alternatively thereto, the substrate 30 may be displaced further continuously, for example, at a constant feed velocity. Also in this case, multiple layers of identical or different materials or identical or different material combinations may be deposited on the substrate or removed therefrom, if the peripheral velocity, i.e., the velocity at which the gas outlets 50 and/or gas inlets 51 move, for example, of the processing head 22 is greater than the feed velocity of the substrate 30. For example, independently of the above-explained feed types, the first to fourth layer structures 200 to 204 may be generated. An average feed velocity of the substrate 30 may be in a range between 0 and 100 m/min, wherein 0 m/min may occur, for example, temporarily during cyclic feed, for example, between 0.1 and 10 m/min, for example, between 0.5 and 5 m/min. The peripheral velocity of the processing head 22 may be greater than the feed velocity of the substrate 30. If multiple processing heads 22 are arranged in succession for the treatment of the same substrate 30, the feed velocity may be increased.

During one coating cycle or during one revolution of the processing head 22, for example, a layer growth of 0.1 nm/cycle is possible. Assuming a rotational velocity of 200 RPM, an ALD layer thickness of 20 nm may thus be achieved after 60 seconds. Assuming a processing head 22 having a radius of 11 cm, a circumference of the jacket surface is 69.1 cm, whereby a coating length of the substrate of approximately 0.6 m results. Therefore, for the roll-to-roll process, a layer growth of 20 nm at a coating velocity of 0.6 m/min is possible. In this case, one of the processing chambers 100, 110, 120, 130, for example, moves in 24 ms over a predefined point on the substrate 30.

Assuming a processing head 22 having a radius of 55 cm, a coating velocity of 5*0.6 m/min results, i.e., 3 m/min, i.e., large-scale industrial production lines are implementable. Assuming these parameters, the individual processes may be carried out partially at room temperature in dependence on the precursors used.

In a step S10, the substrate 30 having the treated surface may be separated. For example, the treated substrate 30 may be unrolled from the roll and/or cut, sawn, or etched.

FIG. 12 shows a flow chart of an embodiment of a method for coating the surface of the substrate 30, which may be carried out in step S6 of the above-explained method, for example. The coating method may be a CVD process or an ALD process, for example. For example, mono-atomic or multi-atomic layers may be applied, which may have a thickness from a few angstroms up to several nanometers. For example, 100 to 200 identical or different layers lying one on top of another may be applied to the substrate 30, for example, according to the first to third layer structures 200, 202, 204.

The flow chart abstractly describes the coating process viewed from an exemplary predefined position on the substrate 30, for example, viewed from the predefined position A. The mentioned processing chambers move during the method over the predefined position A. The individual steps are executed permanently; however, the processing chambers rotate over the substrate 30, so that viewed from the predefined position A on the substrate 30, a chronological sequence of the individual steps results. The flow chart is therefore executed at different points in time at different positions on the substrate 30. Furthermore, the method represents an idealized processing sequence, during which no entrainment of the process gases from one processing chamber to another occurs, which may be at least nearly achieved with the aid of the transverse walls 131, for example. However, even if the transverse walls are used and to a substantial extent without the transverse walls 131, entrainment does occur, so that, for example, whenever a process gas is suctioned out, the process gas of the preceding processing chamber is also suctioned out and therefore mixing of the process gases in the gas phase occurs at least during the suctioning out. Undesired reactions of the reaction gases with one another may be prevented by always using the flushing gas between two reaction gases, since then only mixing of one of the reaction gases with the flushing gas occurs during the suctioning out. The case in which the entrainment more or less occurs, for example, if the height of the transverse walls 131 is less than the height of the processing chambers or if the transverse walls 131 are omitted, will be explained in greater detail hereafter with reference to FIG. 17.

If an ALD process is carried out, thus, for example, to produce the first layer 210, first a first gaseous educt, then a flushing gas, and then a second gaseous educt may be supplied successively via the rotating processing head 22. The educts may also be referred to as precursors. The first educt may have water, for example, and the second educt may have trimethyl aluminum (TMA), for example, whereby an Al₂O₃ layer may be generated. Alternatively or additionally, for example, TiCl₄ may be used as the second educt.

For example, in a step S12, the first process gas may be supplied, which corresponds to the first educt, for example, the first reaction gas. The first process gas may be supplied to the first processing chamber 100, for example. Atoms and/or molecules of the first process gas may accumulate in this case on the surface of the substrate 30 to be treated. For example, the surface of the substrate 30 to be coated is saturated with the gas atoms or gas molecules of the first gaseous educt. The first educt may include, for example, water vapor, oxygen, or ozone.

In a step S14, the first process gas may be suctioned out, for example, via the sixth processing chamber 132, which follows the first processing chamber 100 opposite to the rotational direction 25.

In a step S16, the flushing gas may be supplied, which mixes with the residual first process gas. The flushing gas may be supplied, for example, to the fifth processing chamber 134, which follows the first processing chamber 100 opposite to the rotational direction 25. The flushing gas substantially suppresses mixing of different educts. In other words, mixing of the substances or gas atoms or gas molecules of the gaseous precursors and therefore an undesired gas phase reaction is prevented by the flushing gas. In addition, a rapid removal of one of the process gases until the supply of a next one of the process gases is thus ensured. An inert gas may be used as a flushing gas. Step S16 and further steps, in which flushing gas is supplied, may also be referred to in general as “purge” steps.

In a step S18, the flushing gas may be suctioned out with the residual first process gas, for example, via the sixth processing chamber 132, which follows the above-mentioned fifth processing chamber 134 opposite to the rotational direction. In this case, a partial vacuum or a predefined differential pressure of an absolute value of 0.001 to 1 bar, for example, in relation to an adjoining processing chamber may be generated in the processing chamber. The differential pressure may also be a pressure difference between two pressures at the predefined position A on the substrate 30 at different points in time, for example.

In a step S20, the second process gas may be supplied, which corresponds to the second educt, for example, the second reaction gas. The second process gas may be supplied to the second processing chamber 110, for example. Atoms and/or molecules of the second process gas may accumulate on the layer made of the first educt and form a compound with it in this case, whereby the first layer 210 is formed, for example, during a single revolution of the processing head 22. The first layer 210 may thus be implemented as mono-atomic, for example. The second educt may be TMA, for example.

In a step S22, the second process gas may be suctioned out, for example, via the sixth processing chamber 132, which follows the second processing chamber 110 opposite to the rotational direction 25.

In a step S24, the flushing gas may be supplied, which mixes with the residual second process gas. The flushing gas may, for example, be supplied to the fifth processing chamber 134, which follows the second processing chamber 120 opposite to the rotational direction 25.

In a step S26, the flushing gas may be suctioned out with the residual second process gas, for example, via the sixth processing chamber 132, which follows the above-mentioned fifth processing chamber 134 opposite to the rotational direction 25.

The first and the second educts may be supplied multiple times in succession repeatedly, for example, to produce multiple layer sequences of the first layer 210. For example, steps S12 to S26 may be carried out multiple times in succession. Steps S12 to S26 may each be carried out during one revolution of the processing head 22. During one revolution, this enables a layer of a first ALD layer to be applied, for example, according to the first layer structure 200. Alternatively thereto, steps S12 to S26 may be carried out multiple times during one revolution, for example, in that the first and the second process gas are supplied via further ones of the gas outlets 50. During one revolution, for example, this enables two or more layers of the first ALD layer to be applied, for example, according to the first layer structure 200. Furthermore, in this case the one or the multiple ALD layers may be formed alternatively or additionally during multiple revolutions.

The coating may be performed, for example, during the cyclic feed of the substrate 30. In this case, the substrate 30 is only conveyed further by a section in each case which approximately corresponds to the circumference of the processing head 22; however, the substrate 30 is not conveyed further during the coating. The processing head 22 is then only supplied with the process gases required for the respective layer, while all other processing chambers, supplies, and discharges are flushed with flushing gas or suctioned out, for example. Layers of arbitrary thickness may thus be implemented.

In addition, further gaseous educts may also be supplied, to produce different layers. For example, two or more further layers may be formed during one or during further revolutions of the processing head 22, for example, according to the second layer structure 202, and/or further layers made of the same material or materials or material combinations may be formed during further revolutions, for example, according to the third layer structure 204. This enables multiple layers of a first ALD layer and then multiple layers of a second ALD layer to be applied.

For example, in a step S30, the third process gas may be supplied, which corresponds to a third educt, for example, the third reaction gas. The third process gas may be supplied, for example, to the third processing chamber 120. Atoms and/or molecules of the third process gas may accumulate in this case on the first layer 210. For example, the first layer 210 is saturated with the third gaseous educt.

In a step S32, the third process gas may be suctioned out, for example, via the sixth processing chamber 132, which follows the third processing chamber 120 opposite to the rotational direction 25.

In a step S34, the flushing gas may be supplied, which mixes with the residual third process gas. The flushing gas may be supplied, for example, to the fifth processing chamber 134, which follows the third processing chamber 110 opposite to the rotational direction 25.

In a step S36, the flushing gas may be suctioned out with the residual third process gas, for example, via the sixth processing chamber 132 following the above-mentioned fifth processing chamber 134 opposite to the rotational direction. In this case, a partial vacuum or a differential pressure of an absolute value of 10 to 100 mbar, for example, may be generated in the sixth processing chamber 132.

In a step S38, the fourth process gas may be supplied, which corresponds to a fourth educt, for example, the fourth reaction gas. The fourth process gas may be supplied to the fourth processing chamber 130, for example. Atoms and/or molecules of the fourth process gas may accumulate in this case on the layer made of the third educt and form a compound with it, whereby, for example, the second layer 220 is formed, for example, during a single revolution of the processing head 22. The second layer 220 may thus be implemented as mono-atomic, for example.

In a step S40, the fourth process gas may be suctioned out, for example, via the sixth processing chamber 132, which follows the fourth processing chamber 130 opposite to the rotational direction 25.

In a step S42, the flushing gas may be supplied, which mixes with the residual fourth process gas. The flushing gas may be supplied, for example, to the fifth processing chamber 134, which follows the fourth processing chamber 130 opposite to the rotational direction 25.

In a step S44, the flushing gas may be suctioned out with the residual fourth process gas, for example, via the sixth processing chamber 132, which follows the above-mentioned fifth processing chamber 134 opposite to the rotational direction 25.

The third and the fourth educts may be supplied repeatedly multiple times in succession, for example, to produce multiple layers 220 of the second layer 220. For example, steps S30 to S44 may be carried out multiple times in succession. This enables multiple layers 220 of a second ALD layer to be applied. Furthermore, steps S12 to S26 and/or S30 to S44 may be carried out multiple times in succession, to implement the different layer structures 200, 202, 204 made of ALD layers.

During the production of an optoelectronic component, the layers 210, 220, for example, the ALD layers may form one, two, or more electrode layers, organic functional layers, optical layers, for example, reflection layers or transmission layers, layers of thin-film transistors, barrier layers, and/or encapsulation layers or be formed thereon.

In various embodiments, the electrode layer may be formed from or may be an electrically conductive material, for example, a metal or a transparent conductive oxide (TCO), or a layer stack of multiple layers of the same metal or different metals and/or the same TCO or different TCOs. Transparent conductive oxides are transparent, conductive materials, for example, metal oxides, for example, zinc oxide, tin oxide, cadmium oxide, titanium oxide, indium oxide, or indium-tin oxide (ITO). In addition to binary metal oxygen compounds, for example, ZnO, SnO2, or In2O3, ternary metal oxygen compounds, for example, AlZnO, Zn2SnO4, CdSnO3, ZnSnO3, MgIn2O4, GaInO3, Zn2In2O5, or In4Sn3O12 or mixtures of different transparent conductive oxides are also included in the group of the TCOs and may be used in various embodiments. Furthermore, the TCOs do not necessarily correspond to a stoichiometric composition and may furthermore be p-doped or n-doped. Furthermore, the electrode layer may include, for example, Ag, Pt, Au, Mg, Al, Ba, In, Ag, Au, Mg, Ca, Sm, or Li, and also compounds, combinations, or alloys of these materials. For example, the electrode layer may be formed by a layer stack of a combination of a layer of a metal on a layer of a TCO, or vice versa. One example is a silver layer, which is applied to an indium-tin oxide layer (ITO) (Ag on ITO) or ITO-Ag-ITO multilayers. Furthermore, the electrode layer may provide one or more of the following materials alternatively or additionally to the above-mentioned materials: networks made of metallic nanowires and nanoparticles, for example, made of Ag; networks made of carbon nanotubes; graphene particles and layers; networks made of semiconductive nanowires. Furthermore, the electrode layer may include electrically conductive polymers or transition metal oxides or electrically conductive transparent oxides.

In various embodiments, an organic functional layer may contain one or more emitter layers, for example, having fluorescent and/or phosphorescent emitters, and also one or more hole conduction layers (also referred to as hole transport layer(s)) and/or one or more electron conduction layers (also referred to as electron transport layer(s)). Examples of emitter materials which may be used for the emitter layer(s) include organic or organometallic compounds, such as derivatives of polyfluorene, polythiophene, and polyphenylene (for example, 2-substituted or 2,5-substituted poly-p-phenylene vinylene) and also metal complexes, for example, iridium complexes such as blue phosphorescent FIrPic (bis(3,5-difluoro-2-(2-pyridyl)phenyl-(2-carboxypyridyl)iridium III), green phosphorescent Ir(ppy)3 (tris(2-phenylpyridine)iridium III), red phosphorescent Ru (dtb-bpy)3*2(PF6) (tris[4,4′-di-tert-butyl-(2,2′)-bipyridine]ruthenium(III) complex), and blue phosphorescent DPAVBi (4,4-bis[4-(di-p-tolylamino)styryl]biphenyl), green fluorescent TTPA (9,10-bis[N,N-di-(p-tolyl)-amino]anthracene), and red fluorescent DCM2 (4-dicyanomethylene)-2-methyl-6-julolidyl-9-enyl-4H-pyrane) as non-polymer emitters. Furthermore, polymer emitters may be used. The emitter materials may be embedded in a suitable manner in a matrix material. It is to be noted that other suitable emitter materials are also provided in other embodiments. The organic functional layer may in general include one or more functional layers. The one or more functional layers may include organic polymers, organic oligomers, organic monomers, organic small, non-polymer molecules (“small molecules”), or a combination of these materials. For example, the organic functional layer may include one or more functional layers, which is or are embodied as a hole transport layer, so that, for example, in the case of an OLED, effective hole injection into an electroluminescent layer or an electroluminescent region is enabled. Alternatively, in various embodiments, the organic functional layer may include one or more functional layers, which is or are embodied as an electron transport layer, so that, for example, in an OLED, an effective electron injection into an electroluminescent layer or an electroluminescent region is enabled. For example, tertiary amines, carbazole derivatives, conductive polyaniline, or polyethylene dioxythiophene may be used as the material for the hole transport layer. In various embodiments, the one or more functional layers may be embodied as an electroluminescent layer.

In various embodiments, an encapsulation layer may include or consist of one of the following materials: aluminum oxide, zinc oxide, zirconium oxide, titanium oxide, hafnium oxide, tantalum oxide, lanthanum oxide, silicon oxide, silicon nitride, silicon oxynitride, indium-tin oxide, indium-zinc oxide, aluminum-doped zinc oxide, and mixtures and alloys thereof. In various embodiments, the encapsulation layer or (in the case of a layer stack having a plurality of partial layers) one or more of the partial layers of the encapsulation layer may include one or more highly-refractive materials, in other words, one or more materials having a high index of refraction, for example, having an index of refraction of at least 2, for example, MoO₃.

In various embodiments, a barrier layer may include or consist of one or more of the following materials: aluminum oxide, zinc oxide, zirconium oxide, titanium oxide, hafnium oxide, tantalum oxide, lanthanum oxide, silicon oxide, silicon nitride, silicon oxynitride, indium-tin oxide, indium-zinc oxide, aluminum-doped zinc oxide, and mixtures and alloys thereof.

As first precursors and/or first reaction gas, for example, to form oxides, oxygen sources may be used, for example, H₂O, H₂O₂. N₂O₄, N₂O, O₂, O₃, CH₃COOH, ROH (where R is equivalent to CH₃, CH₂OHCH₂OH, t-C₄H₉OH, or n-C₄H₉OH) or metal alkoxides, to form nitrides, nitrogen sources may be used, for example, NH₃, (CH₃)NNH₂, tBuNH₂, or CH₂CHCH₂NH, to form pure metals, for example, H₂, B₂H₆, silanes, or hydrides may be used, to form sulfides, selenides, or tellurides, for example, H₂S, H₂Se, or H₂Te, respectively, may be used.

As second precursors and/or second reaction gas, for example, to form Al₂O₃, for example, (CH₃)₃Al, (CH₃)₂AlCl, (CH₃)₂AlH, or (CH₃CH₂)₃Al may be supplied, to form ZnO, for example, (CH₃)₄Zn, (CH₃CH₂)₄Zn, or (C₂H₅)₂Zn may be supplied, to form ZrO₂, for example, (C₅H₅)₂ZrCl₂, (C₅H₅)₂Zr(CH₃)₂, Zr[(C₂H₅)(CH₃)N]₄, ZrCl₄, or Zr(CH₃C₅H₄)₂CH₃OCH₃ may be supplied, to form TiO2/TiN, for example, Ti(OCH(CH₃)₂)₄, Ti[N(CH₃)₂]₄, TiCl₄, or [(C₂H₅)₂N]₄Ti may be supplied, to form HfO₂, for example, (C₅H₅)₂HfCl₂, (C₅H₅)₂Hf(CH₃)₂, Hf[(C₂H₅)(CH₃)N]₄, HfCl₄, Hf[C₅H₄(CH₃)]₂(CH₃)₂, or HfCH₃(OCH₃)[C₅H₄(CH₃)]₂ may be supplied, to form Ta₂O₅/Ta₃N₅, for example, TaCl₅ or (CH₃)₃CNTa(N(C₂H₅)₂)₃ may be supplied, to form La₂O₃, for example, (C₅H₅)₃La or (C₅MeH₄)₃La may be supplied, to form SiO₂/SiN, for example, SiCl₄, Si(O(CH₂)₃CH₃)₄, ((CH₃)₃CO)₃SiOH, (CH₃CH₂C(CH₃)₂O)₃SiOH, or (HSiCH₃O)₄ may be supplied, to form SnO₂, for example, (CH₃)₄Sn or (CH₃CH₂)₄Sn may be supplied, to form ITO, for example, In(OCCH₃CHOCCH₃)₃, (CH₃)₄Sn, or (CH₃CH₂)₄Sn may be supplied, to form MgO, for example, (C₅H₅)₂Mg may be supplied, to form Sc₂O₃, for example, (C₅H₅)₃Sc may be supplied, to form Y₂O₃, for example, (C₅H₅)₃Y or (C₅MeH₄)₃Y may be supplied, to form Pt, for example, (C₅MeH₄)₃PtMe₃ or C₅H₄CH₃Pt (CH₃)₃ may be supplied, to form NiO, for example, (C₅H₅)₂Ni or Ni(C₅H₄C₂H₅)₂ may be supplied, to form V₂O₅, for example, OV(OCH(CH₃)₂)₃ may be supplied, to form Fe₂O₃, for example, {(CH₃)₃CO)₃Fe}₂ may be supplied, to form WN, for example, ((CH₃)₃CN)₂W(N(CH₃)₂)₂ may be supplied, to form GaAs, for example, (CH₃CH₂)₃Ga, Ga(CH₃)₃, (C₆H₅)₃As, or (C₆H₅)₂AsCH₂CH₂As (C₆H₅)₂ may be supplied, to form ZnS, for example, (CH₃)₄Zn, (CH₃CH₂)₄Zn, or (C₂H₅)₂Zn may be supplied, to form CdS, for example, Cd(C₂H₇O₂)₂ may be supplied, to form B₂O₃, for example, (C₆H₅)₃B or [(CH₃)₂CHO]₃B may be supplied, to form Pd, for example, Pd (C₅H₇O₂)₂ may be supplied, to form BaO, for example, Ba (OCC(CH₃)₃CHCOCF₂CF₂CF₃)2 may be supplied, to form SrO, for example, Sr(OCC(CH₃)₃CHCOCF₂CF₂CF₃)₂ or C₂₂H₃₈O₄Sr may be supplied, or to form MoO₃, for example, C₁₁H₈MoO₄, C₁₀H₁₀Cl₂Mo, [(C₆H₅)₂PCH₂CH₂P(C₆H₅)₂]Mo(CO)₄, C₁₆H₁₀Mo₂O₆, MO(CO)₆, MO(CO)₆, C₂₂H₂₂Mo₂O₆, C₇H₈Mo(CO)₃, or Mo(NCCH₃)₃(CO)₃ may be supplied.

Before the supply of the process gases into the processing chambers 100, 110, 120, 130, a partial vacuum close to vacuum may be produced or not produced in the corresponding processing chambers. Furthermore, multi-atomic layers may be implemented.

FIG. 13 shows an embodiment of the device 10 for the treatment of the surface of the substrate 30, which includes multiple processing units 20 arranged in series having processing heads correspondingly arranged in series. The fact that the processing heads 22 are arranged in series means in this context that the substrate 30 successively passes through the individual processing units 20 going past the corresponding processing heads 22. The processing heads 22 are arranged, for example, so that the same side of the substrate 30 is treated by the or one of the following processing heads 22 as by the preceding processing head 22. Further layers and/or, for example, alternating layers or layer packets may thus be applied or a previously applied layer may be entirely or partially ablated. Alternatively or additionally, if the layer structure remains uniform, the layers as a whole may be applied more rapidly, for example, the feed velocity may be increased.

FIG. 14 shows a further embodiment of the device 10 for the treatment of the surface of the substrate 30, which has multiple processing units 20 arranged in series having processing heads 22 correspondingly arranged in series. The processing heads 22 are arranged, for example, so that by way of the or one of the following processing heads 22, the other side of the substrate 30 and therefore another surface of the substrate 30 is treated than by the preceding processing head 22. In this way, layers may be applied to the other surface of the substrate 30 or a layer previously applied to the other side may be entirely or partially ablated.

FIG. 15 shows an embodiment of a processing head, for example, the processing head 22 in a side view, wherein the substrate 30 is only indicated in a sectional view. In this embodiment of the processing head 22, the transverse walls 131 are only optionally arranged and are illustrated by dashed lines in FIG. 15. One of the gas outlets 50 and one of the gas inlets 51 are each implemented by a slotted recess. In addition, multiple spacers 140 are arranged around the circumference of the processing head 22. The spacers 140 are used for the purpose of predefining a spacing of the substrate 30 from the processing head 22 and therefore a height of the processing chambers 110, 132, 134. The spacers 140 may be arranged additionally or alternatively to the webs 102, 104. In addition, the transverse walls 131 may additionally or alternatively assume the function of the spacers 140. In the embodiment shown in FIG. 15, the spacers 140 are implemented as spherical and are rotatably mounted in corresponding recesses of the processing head 22, so that in operation, friction between the spacers 140 and the substrate 30 may be kept low. Alternatively to the spherical shape, the spacers 140 may also be implemented in the form of rollers, for example, and/or may extend parallel to the axis of rotation 58, for example, wherein the spacers 140 may then also be rotatably mounted in corresponding recesses of the processing head 22. The spacers 140 may also contribute to being able to treat relatively wide substrates 30.

FIG. 16 shows a further embodiment of a processing head, for example, the processing head 22 in a side view, wherein the substrate 30 is only indicated in a sectional view. In this embodiment of the processing head 22, the processing head 22 includes a jacket surface which is curved concavely, i.e., inward. This may contribute, for example, to the substrate 30 sagging inward, and nonetheless the desired height of one or more of the processing chambers 100, 110, 132, 134 being ensured. The gas inlets 50 and/or the gas outlets 51 are implemented in this embodiment, for example, by circular recesses. In addition, multiple circular recesses each form one of the gas inlets 50 or the gas outlets 51. The circular recesses may be implemented additionally or alternatively to the slotted recesses. Furthermore, more or fewer and/or larger or smaller recesses may be implemented. Furthermore, the recesses may be implemented at greater or smaller spacings to one another. Independently of the shape of the recesses, the recesses themselves and/or their profiles and/or extensions in the processing head 22 may be implemented to take into consideration a gas flow during operation. For example, the recesses may be implemented in a flow-optimized manner. For example, the widths of the openings of the slots may vary in the direction perpendicular to the axis 58.

The spacers 140 are implemented, for example, so that the substrate 30 has, for example, a spacing between 0.01 and 10 mm, for example, between 0.05 and 5 mm, for example, between 0.1 and 1 mm from the jacket surface of the processing head 22. The processing chamber or chambers then have a height, when the flexible substrate 30 is applied, between 0.01 and 10 mm, or between 0.05 and 5 mm, or between 0.1 and 1 mm, respectively.

Alternatively or additionally, the spacing of the substrate 30 from the processing head 22 may be predefined in that the substrate 30 is suctioned away from the processing head 22 with the aid of a partial vacuum on the side of the substrate 30 facing away from the processing head 22.

In all of the above-explained embodiments, the mentioned processing chambers may be more or less separated from one another. The separation may be relatively extensive in this case, for example, with the aid of the transverse walls 131, so that the processing chambers are discretely separated from one another, for example. However, the separation may also be reduced, for example, with decreasing height of the transverse walls 131. This may extend, for example, enough that the transverse walls 131 no longer separate the processing chambers from one another and/or the transverse walls 131 are completely omitted. The individual processing chambers then merge continuously into one another. Furthermore, the processing chambers are then characterized and/or defined by the gas cushions, in which one of the process gases is located or in which the process gases are discharged. As the separation becomes less, mixing of the process gases and therefore entrainment of the process gases during the operation of the device 10 increase. Undesired reactions of the process gases with one another as a result of the entrainment may be prevented or at least kept small, for example, by a suitable selection of the partial pressures in the processing chambers or the shared processing chamber. The partial pressures may be set via the supply and/or the discharge of the process gases. For example, a pressure in the housing 24 may be greater or less than an ambient pressure of the housing 24. For example, a mean pressure in the processing chambers may approximately correspond to the pressure in the housing 24. For example, the mean pressure in the processing chambers may be between 0.001 and 5 bar, for example, between 0.01 and 2 bar. For example, the pressure in the region of the gas outlets 50 may be greater than in the region of the gas inlets 51, for example, so that a sufficient flow occurs and/or no enrichment of precursors results in flushing gas chambers, i.e., processing chambers to which flushing gas is supplied. For example, a mean pressure of the flushing gas may be kept greater than a mean pressure of the precursors. Alternatively or additionally, a flow of the flushing gas may be set to be greater than a flow of the precursors, whereby the entrainment may be kept small or prevented, for example.

FIG. 17 shows a graph to illustrate a functional principle of the device 10 for the surface treatment of the substrate 30. In addition, FIG. 17 illustrates the entrainment of the process gases in operation of the device 10. In particular, FIG. 17 shows the dependence of the concentration c of the process gases on the time t at the predefined position A on the substrate 30. In this case, the substrate 30 may be stationary, for example, in cyclic feed operation, or the substrate 30 may move, for example, at one of the above-mentioned feed velocities. During the time t, the processing chambers move over the predefined position A, so that different process gases in different concentrations are moved over the predefined position A on the substrate 30 in the time curve. In other words, in the time curve, gas cushions which have different concentrations of process gases are moved over the predefined position A on the substrate 30. At another position of the substrate 30, which is remote along the circumference of the processing head 22 from the predefined position A, the different concentrations also occur, but at different points in time, wherein the graphs corresponding to the individual other positions are time-shifted and/or phase-shifted in relation to the graph shown in FIG. 17.

In a first time interval 210, the concentration c of the first reaction gas, which is shown as a dash-dot line, increases at the position A up to a maximum value, which is then maintained for a predefined duration. The duration is essentially predefined by the rotational velocity of the processing head 22. During the first time interval 210, for example, the first processing chamber 100 moves over the predefined position A, as shown in FIG. 7.

Adjoining the first time interval 210, i.e., between the first time interval 210 and a second time interval 220, the first reaction gas is suctioned out, for example, while the sixth processing chamber 132 adjoining the first processing chamber 100 moves over the predefined position A. Therefore, entrainment of the first reaction gas from the first processing chamber 100 to the following sixth processing chamber 132 occurs. In addition, flushing gas is drawn in from the fifth processing chamber 134 following the sixth processing chamber 132, which represents an entrainment of the flushing gas. Therefore, mixing of the first reaction gas and the flushing gas occurs in the sixth processing chamber 132 following the first processing chamber 100.

In the second time interval 220, the concentration c, which is shown as a solid line and which is then maintained for a predefined duration, of the flushing gas is maximal at the position A. The duration is essentially predefined by the rotational velocity of the processing head 22. The first reaction gas is completely or nearly completely suctioned out, so that mixing of the first reaction gas with the following second reaction gas to be supplied is avoided in the gas phase. During the second time interval 220, for example, the fifth processing chamber 134, which lies between the first and second processing chambers 100, 110, moves over the predefined position A.

Adjoining the second time interval 220, i.e., between the second time interval 220 and a third time interval 230, the flushing gas is suctioned out, for example, while the sixth processing chamber 132, which lies before the second processing chamber 110, moves over the predefined position A. Therefore, entrainment of the flushing gas occurs from the fifth processing chamber 134 to the following sixth processing chamber 132. In addition, the second reaction gas is drawn in from the second processing chamber 110 following the sixth processing chamber 132, which represents an entrainment of the second reaction gas. Therefore, mixing of the second reaction gas and the flushing gas occurs in the sixth processing chamber 132, which lies before the second processing chamber 110.

In the third time interval 230, the concentration c of the second reaction gas, which is shown as a dash-double dot line, is maximal at the position A, and then the maximum concentration c is maintained for a predefined duration. The duration is essentially predefined by the rotational velocity of the processing head 22. During the third time interval 230, for example, the second processing chamber 110 moves over the predefined position A.

Adjoining the third time interval 230, i.e., between the third time interval 230 and a fourth time interval 240, the second reaction gas is suctioned out, for example, while the sixth processing chamber 132, which adjoins the second processing chamber 110, moves over the predefined position A. Therefore, entrainment of the second reaction gas occurs from the second processing chamber 110 to the following sixth processing chamber 132. In addition, flushing gas is drawn in from the fifth processing chamber 134 following the sixth processing chamber 132, which represents entrainment of the flushing gas. Therefore, mixing of the second reaction gas and the flushing gas occurs in the sixth processing chamber 132 following the second processing chamber 110.

After passage of the third time interval 230, for example, a first ALD layer is applied at the predefined position A. Subsequently, a further ALD layer may be applied at the predefined position to the substrate 30, for example, a layer of the same material with the aid of the same reaction gases, for example, with the aid of the first and second reaction gases, or a layer of another material with the aid of other reaction gases, for example, with the aid of the third and fourth reaction gases.

In the fourth time interval 240, the concentration c of the flushing gas is maximal at the position A, which is then maintained for a predefined duration. The duration is essentially predefined by the rotational velocity of the processing head 22. The second reaction gas is completely or nearly completely suctioned out, so that mixing of the second reaction gas in the gas phase with the reaction gas subsequently supplied to the substrate 30 at the predefined position A is avoided. During the fourth time interval 240, for example, the fifth processing chamber 134, which lies between the second and third processing chambers 110, 120, moves over the predefined position A.

Adjoining the fourth time interval 240, i.e., between the fourth time interval 240 and a fifth time interval 250, the flushing gas is suctioned out, for example, while the sixth processing chamber 132, which lies before the third processing chamber 120, moves over the predefined position A. Therefore, entrainment of the flushing gas occurs from the fifth processing chamber 134 to the following sixth processing chamber 132. In addition, from the third processing chamber 120 following the sixth processing chamber 132, the process gas located therein, for example, the third reaction gas, is drawn in, which represents entrainment of the third reaction gas. Therefore, mixing of the third reaction gas and the flushing gas occurs in the sixth processing chamber 132 lying before the third processing chamber 120.

In the fifth time interval 250, the concentration c of the third reaction gas, which is shown as a dash-dot line, increases up to a maximum value at the position A, which is then maintained for a predefined duration. The duration is essentially predefined by the rotational velocity of the processing head 22. During the fifth time interval 250, for example, the third processing chamber 120 moves over the predefined position A. Alternatively thereto, in the fifth time interval 250, the first reaction gas may also be supplied again at the predefined position A.

Adjoining the fifth time interval 250, i.e., between the fifth time interval 210 and a sixth time interval 260, the third reaction gas is suctioned out, for example, while the sixth processing chamber 132, which adjoins the third processing chamber 120, moves over the predefined position A. Therefore, entrainment of the third reaction gas occurs from the third processing chamber 120 to the following sixth processing chamber 132. In addition, flushing gas is drawn in from the fifth processing chamber 134 following the sixth processing chamber 132, which represents entrainment of the flushing gas. Therefore, mixing of the third reaction gas and the flushing gas occurs in the sixth processing chamber 132, which follows the third processing chamber 100.

In the sixth time interval 260, the concentration c of the flushing gas is maximal at the position A, which is shown as a solid line and is then maintained for a predefined duration. The duration is essentially predefined by the rotational velocity of the processing head 22. The third reaction gas is completely or nearly completely suctioned out, so that mixing of the third reaction gas with the fourth reaction gas in the gas phase is avoided. During the sixth time interval 260, for example, the fifth processing chamber 134, which lies between the third and fourth processing chambers 120, 130, moves over the predefined position A.

Adjoining the sixth time interval 260, i.e., between the sixth time interval 260 and a seventh time interval 270, the flushing gas is suctioned out, for example, while the sixth processing chamber 132, which lies before the fourth processing chamber 130, moves over the predefined position A. Therefore entrainment of the flushing gas occurs from the fifth processing chamber 134 to the following sixth processing chamber 132. In addition, the fourth reaction gas is drawn in from the fourth processing chamber 130 following the sixth processing chamber 132, which represents entrainment of the fourth reaction gas. Therefore, mixing of the fourth reaction gas and the flushing gas occurs in the sixth processing chamber 132, which lies before the fourth processing chamber 110.

In the seventh time interval 270, the concentration c of the fourth reaction gas, which is shown as a dash-double dot line, is maximal at the position A, and the maximum concentration c is then maintained for a predefined duration. The duration is essentially predefined by the rotational velocity of the processing head 22. During the seventh time interval 270, for example, the third processing chamber 110 moves over the predefined position A. Alternatively thereto, in the seventh time interval 270, for example, the second reaction gas may again be supplied to the substrate 30 at the predefined position A.

Adjoining the seventh time interval 270, i.e., between the seventh time interval 270 and an eighth time interval 280, the fourth reaction gas is suctioned out, for example, while the sixth processing chamber 132 adjoining the fourth processing chamber 130 moves over the predefined position A. Therefore, entrainment of the fourth reaction gas occurs from the fourth processing chamber 130 to the following sixth processing chamber 132. In addition, flushing gas is drawn in from the fifth processing chamber 134 following the sixth processing chamber 132, which represents entrainment of the flushing gas. Therefore, mixing of the fourth reaction gas and the flushing gas occurs in the sixth processing chamber 132, which follows the fourth processing chamber 110.

After passage of the seventh time interval 270, for example, a second ALD layer is applied at the predefined position A. Subsequently, a further ALD layer may be applied at the predefined position A to the substrate 30, for example, a layer of the same material with the aid of the same reaction gases, for example, with the aid of the third and fourth reaction gases, or a layer of another material with the aid of other reaction gases, for example, with the aid of the first and second reaction gases.

In the eighth time interval 280, the concentration c of the flushing gas is maximal at the position A, which is then maintained for a predefined duration. The duration is essentially predefined by the rotational velocity of the processing head 22. The fourth reaction gas is completely or nearly completely suctioned out, so that mixing of the fourth reaction gas with a reaction gas subsequently supplied to the substrate 30 at the predefined position A is avoided. During the eighth time interval 280, for example, the fifth processing chamber 134, which lies between the fourth and first processing chambers 130, 100, moves over the predefined position A.

Adjoining the eighth time interval 280, the flushing gas is suctioned out, for example, while the sixth processing chamber 132, which lies before the first processing chamber 100, moves over the predefined position A. Therefore, entrainment of the flushing gas occurs from the fifth processing chamber 134 to the following sixth processing chamber 132. In addition, from the first processing chamber 100, which follows the sixth processing chamber 132, the process gas located therein, for example, the first reaction gas, is drawn in, which represents entrainment of the first reaction gas. Therefore, mixing of the first reaction gas and the flushing gas occurs in the sixth processing chamber 132, which lies before the first processing chamber 100.

The graph shown in FIG. 17 relates to an embodiment of the processing head 22, in which no transverse walls 131 are provided and the processing chambers are solely defined by the corresponding process gases and the gas cushions thus formed, which rotate over the predefined position A. Although no transverse walls 131 are arranged, as described above, mixing of different reaction gases in the gas phase does not occur and therefore undesired molecule formation detached from the substrate 30 does not occur. The reactions are restricted solely to the atoms and/or molecules of the reaction gases which are already adsorbed on the surface, for example, the precursors, on the substrate 30. The occurring entrainment and/or mixing of the reaction gases with the flushing gas may be reduced, for example, by increasing the flushing gas flow and/or by wider fifth and/or sixth processing chambers 134, 132 along the circumference of the processing head 22 and/or by stronger suctioning out in the sixth processing chambers 132. A reduction of the spacing between substrate 30 and processing head 22 may also counteract entrainment. This may also contribute to a reduction of the process gas consumption.

If the transverse walls 131 are arranged, a similar graph may be prepared, wherein the corresponding graph differs from the graph shown, for example, between the illustrated time intervals. For example, less entrainment and/or mixing of process gases occurs and/or the slopes of the flanks of the concentration graphs change, for example, in dependence on the height of the transverse walls 131.

The disclosure is not restricted to the specified embodiments. For example, two or more processing heads 22 may be arranged in one housing 24. Furthermore, further processing units 20 may be arranged. For example, the devices 10 shown in FIG. 13 and FIG. 14 may be combined with one another. Furthermore, more or fewer process gases may be supplied and accordingly further or fewer (different) layers, for example, ALD layers, may be implemented. Furthermore, when carrying out the roll-to-roll method, a strip buffer may be arranged or the roll-to-roll method may be carried out without strip buffer. The layer structures 200, 202, 204 may include further or fewer layers 210, 220. Furthermore, arbitrary layer combinations may be generated.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A device for the surface treatment of a substrate, comprising a processing head, which is mounted rotatably about an axis of rotation, and which comprises multiple gas outlets, which are at least partially implemented on a radial outer edge of the processing head.

2. The device as claimed in claim 1,
wherein the gas outlets are implemented and arranged so that in operation a process gas leaves at least one of the gas outlets, so that it flows away from the processing head at least partially in a direction having a radially oriented directional component.

3. The device as claimed in claim 1,
wherein the processing head is implemented as cylindrical and comprises an axis and a jacket surface, wherein the axis lies on the axis of rotation, and wherein the gas outlets arranged on the outer edge are implemented on the jacket surface.

4. The device as claimed in claim 1,
wherein at least one gas inlet is implemented on the radial outer edge of the processing head.

5. The device as claimed in claim 4,
wherein at least one gas outlet and/or the at least one gas inlet, which is arranged on the radial outer edge, are implemented as slotted and/or circular.

6. The device as claimed in claim 1,
wherein the processing head comprises:
a first gas outlet for supplying a first reaction gas to a first processing chamber,
a second gas outlet for supplying a second reaction gas to a second processing chamber, and
a further gas outlet for supplying a flushing gas to a further processing chamber.

7. The device as claimed in claim 1, further comprising a housing (24), in which the processing head is rotatably mounted and which comprises a supply opening for supplying the substrate and a discharge opening for discharging the substrate.

8. The device as claimed in claim 7, further comprising a heating device, which heats an interior of the housing.

9. The device as claimed in claim 7, further comprising a housing suction unit for suctioning gas out of the housing.

10. The device as claimed in claim 7, wherein the housing comprises a housing flushing gas supply for supplying flushing gas into the housing.

11. The device as claimed in claim 1, further comprising a feed device for feeding the substrate toward the processing head and guiding the substrate further away from the processing head.

12. The device as claimed in claim 1, further comprising two or more spacers for predefining a spacing between the substrate and the processing head.

13. The device as claimed in claim 12,
wherein the spacers comprise at least two webs, which are arranged at the axial outer edges of the processing head.

14. The device as claimed in claim 1, further comprising multiple transverse walls on its radial outer edge, which protrude in the radial direction from the radial outer edge and which extend in one direction having a directional component in the axial direction.

15. The device as claimed in claim 1, wherein channels are implemented in the processing head, spaced apart from the radial outer edge, said channels being used for the purpose of connecting the gas outlets and the gas inlets to corresponding gas feedthroughs.

16. The device as claimed in claim 1, further comprising a drive unit for rotating the processing head.

17. The device as claimed in claim 1, further comprising multiple processing heads arranged in series.

18. A method for the surface treatment of a substrate, comprising:
laying the substrate at least partially around a radial outer edge of a rotatably mounted processing head so that a surface of the substrate faces toward the processing head, and a processing chamber is formed between the surface of the substrate and the processing head,
rotating the processing head in relation to the substrate, and
supplying at least one process gas for the treatment of the surface of the substrate facing toward the processing head to the processing chamber via the rotating processing head.

19. The method as claimed in claim 18,
wherein the processing head is implemented and wherein the substrate is laid around the radial outer edge of the processing head so that the processing chamber, which is formed between the radial outer edge of the processing head and the substrate, is delimited by the processing head and the substrate.

20. The method as claimed in claim 18,
wherein a process gas is discharged via the radial outer edge of the processing head.

21. The method as claimed in claim 18,
wherein a coating method is carried out with the aid of the processing head.

22. The method as claimed in claim 21,
wherein an ALD process is carried out.

23. The method as claimed in claim 22,
wherein successively first a first reaction gas, then a flushing gas, and then a second reaction gas are supplied as process gases via gas outlets of the rotating processing head.

24. The method as claimed in claim 18,
wherein the substrate is stopped or guided further during the surface treatment.

25. The method as claimed in claim 18,
wherein a peripheral velocity of the processing head is greater than a feed velocity of the substrate.

26. A method for producing an optoelectronic component, comprising:
a method for the surface treatment of a substrate,
the method comprising:
laying the substrate at least partially around a radial outer edge of a rotatably mounted processing head so that a surface of the substrate faces toward the processing head, and a processing chamber is formed between the surface of the substrate and the processing head,
rotating the processing head in relation to the substrate, and
supplying at least one process gas for the treatment of the surface of the substrate facing toward the processing head to the processing chamber via the rotating processing head,
wherein the substrate is coated with an electrode layer, an optical functional layer, an organic functional layer, a barrier layer, and/or an encapsulation layer.
